(19) United States
(12) Patent Application Publication
(10) Pub. No.: US 2007/0076487 A1
(43) Pub. Date: Apr. 5, 2007

(54) SEMICONDUCTOR INTEGRATED CIRCUIT DEVICE

(76) Inventors: Ken Takeuchi, Yokohama-shi (KR); Koichi Kawai, Yokohama-shi (KR)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/533,205

(22) Filed: Sep. 19, 2006

(30) Foreign Application Priority Data
Sep. 30, 2005 (JP) 2005-288830

(51) Int. Cl. G11C 11/34

(52) U.S. Cl. 365/185.22

(57) ABSTRACT

A semiconductor integrated circuit device has data rewritable nonvolatile memory cells which are formed on a semiconductor chip and in which data of three or more values can be stored. The nonvolatile memory cell has two or more write levels and two or more write threshold voltages are used. The two or more threshold voltage distribution widths are changed according to the two or more write levels.

### CROSS-REFERENCE TO RELATED APPLICATIONS

This application is based upon and claims the benefit of priority from prior Japanese Patent Application No. 2005-288830, filed Sep. 30, 2005, the entire contents of which are incorporated herein by reference.

### BACKGROUND OF THE INVENTION

1. Field of the Invention

This invention relates to a semiconductor integrated circuit device and more particularly to a semiconductor integrated circuit device having an electrically rewritable nonvolatile semiconductor memory device.

2. Description of the Related Art

In an electrically rewritable nonvolatile semiconductor memory device, for example, in a multi-level flash memory, two or more write levels are provided. The distribution widths of write threshold voltages must be made narrow. In order to narrow the distribution width of the write threshold voltage, it is preferable to reduce the step-up width of the write voltage applied to a word line. To reduce the step-up width, must be carefully written bit by bit. Therefore, it takes a long time for writing.

Reference Document: U.S. Pat. No. 6,643,188

### BRIEF SUMMARY OF THE INVENTION

According to one aspect of this invention, a semiconductor integrated circuit device comprises a semiconductor chip, and data rewritable nonvolatile memory cells which are arranged on the chip and in which it is permissible to store data of not smaller than three values, wherein at least two write threshold voltage distribution widths are changed according to at least two write levels.

### BRIEF DESCRIPTION OF THE SEVERAL VIEWS OF THE DRAWING

FIG. 1 is a block diagram showing one example of a semiconductor integrated circuit device according to a first embodiment of this invention;

FIG. 2 is a diagram showing one example of a memory cell array shown in FIG. 1;

FIG. 3 is a cross-sectional view showing one example of the structure in the column direction of the memory cell array shown in FIG. 1;

FIG. 4 is a cross-sectional view showing one example of the structure in the row direction of the memory cell array shown in FIG. 1;

FIG. 5 is a cross-sectional view showing one example of the structure in the row direction of the memory cell array shown in FIG. 1;

FIG. 6 is a block diagram showing one example of a column control circuit shown in FIG. 1;

FIG. 7 is a diagram showing the relation between multi-level data and the threshold voltages of memory cells;

FIG. 8 is a diagram showing a typical write method and threshold voltage control operation;

FIG. 9 is a diagram showing a write method and threshold voltage control operation of the semiconductor integrated circuit device according to the first embodiment;

FIG. 10 is a diagram showing a write method of upper page data and a threshold voltage control operation of the semiconductor integrated circuit device according to the first embodiment;

FIG. 11 is an operation waveform diagram showing waveforms at the write time of lower page data of the semiconductor integrated circuit device according to the first embodiment;

FIG. 12 is a flow chart showing a write algorithm of lower page data of the semiconductor integrated circuit device according to the first embodiment;

FIG. 13 is a flow chart showing a write algorithm of upper page data of the semiconductor integrated circuit device according to the first embodiment;

FIGS. 14A to 14C are views and diagram showing situations caused by miniaturization of the processing dimensions;

FIG. 15 is a diagram showing an order of write operations in the blocks;

FIG. 16 is a diagram showing a read algorithm of lower page data of the semiconductor integrated circuit device according to the first embodiment;

FIG. 17 is a diagram showing a read algorithm of upper page data of the semiconductor integrated circuit device according to the first embodiment;

FIG. 18A is an operation waveform diagram showing a write step example 1;

FIG. 18B is an operation waveform diagram showing a write step example 2;

FIG. 19 is an operation waveform diagram showing a modification of the write verify operation;

FIGS. 20A and 20B are diagrams showing distributions of the threshold voltages of a NAND flash memory according to the first embodiment of this invention;

FIG. 21 is a diagram showing the effect attained in the first embodiment;

FIG. 22 is a diagram showing the effect attained in the first embodiment;

FIGS. 23A and 23B are diagrams showing distributions of the threshold voltages of a NAND flash memory according to a second embodiment of this invention;

FIG. 24 is a diagram showing distributions of the threshold voltages of a NAND flash memory according to a first modification of the second embodiment of this invention;

FIG. 25 is a diagram showing distributions of the threshold voltages of a NAND flash memory according to a second modification of the second embodiment of this invention;

FIG. 26 is a diagram showing distributions of the threshold voltages of a NAND flash memory according to a first example of a third embodiment of this invention;

FIG. 27 is a diagram showing distributions of the threshold voltages of a NAND flash memory according to a second example of the third embodiment of this invention;

FIG. 28 is a diagram showing definition of a page;

FIG. 29 is a diagram showing a cell into which data is written and cells lying around the above cell;

FIG. 30 is a diagram showing distributions of the threshold voltages of the memory cells at the main write stage;

FIG. 31 is a diagram showing distributions of the threshold voltages of the memory cells at the main write stage;

FIG. 32 is a diagram showing distributions of the threshold voltages of the memory cells at the main write stage;

FIG. 33 is a diagram showing distributions of the threshold voltages of the memory cells at the main write stage;

FIG. 34 is a diagram showing distributions of the threshold voltages of the memory cells at the main write stage;

FIG. 35 is a diagram showing distributions of the threshold voltages of the memory cells at the main write stage;

FIG. 36 is a diagram showing distributions of the threshold voltages of the memory cells at the main write stage; and

FIG. 37 is a diagram showing distributions of the threshold voltages of the memory cells at the main write stage.

### DETAILED DESCRIPTION OF THE INVENTION

Embodiments of this invention will now be described with reference to the accompanying drawings. In this explanation, common reference symbols are assigned to common portions throughout the drawings.

### First Embodiment

In a semiconductor integrated circuit device according to a first embodiment, the distribution width of the write threshold voltages at high write levels, for example, the distribution width of the write threshold voltages at the highest write level is made larger than the distribution width of the write threshold voltages at other write levels. This is based on the fact that a potential difference between the threshold voltage distribution at the high write level, for example, at the highest write level and intermediate voltage Vpass has a larger margin than that between other write levels in many cases.

If the distribution width of the write threshold voltages at the high write level, for example, the distribution width of the write threshold voltages at the highest write level is made larger than the distribution width of the write threshold voltages at the other write levels, then, the step-up width of write voltage applied to a word line can be increased to write the highest write level, for example. Therefore, the write time can be reduced.

Thus, the operation speed can be enhanced while narrow distribution width is provided for the write levels other than the highest write level.

In order to attain the above threshold voltage distribution, some methods other than the method of increasing the step-up width of the write voltage applied to the word line may be used to write the highest write level.

For example, as the above method, a write method of reducing the step-up width when the voltage comes closer to the set write threshold voltage is provided. For example, a write method which is called a pass write method or quick-pass write method is provided.

The pass write method is a method for reducing the distribution width of the write threshold voltages by executing a first program called a 1^{st} Pass and a second program called a 2^{nd} Pass. The step-up width of the second program is smaller than the step-up width of the first program. Thus, small distribution width is realized.

The quick-pass write method is attained by improving the pass write method and is designed to reduce the write time by processing the 1^{st} Pass and 2^{nd} Pass in parallel.

When the pass write method or quick-pass write method is used as the write method, for example, a method of maintaining the step-up width (for example, the pass write method or quick-pass write method is not used for writing of the highest write level) to write the highest write level or making the step-up width at the time of execution of the 2^{nd} Pass at the highest write level larger than the step-up width at the time of execution of the 2^{nd} Pass at another write level can be used, for example.

In the above write method, since the method of writing the highest write level keeps the step-up width unchanged or increases the step-up width at the time of execution of the 2^{nd} Pass, the write time can be reduced as in the above case.

Also, in this case, the distribution width of the write threshold voltages at the highest write level is made larger than the distribution width at another write level like the above case.

There will now be described the first embodiment of this invention with reference to the accompanying drawings.

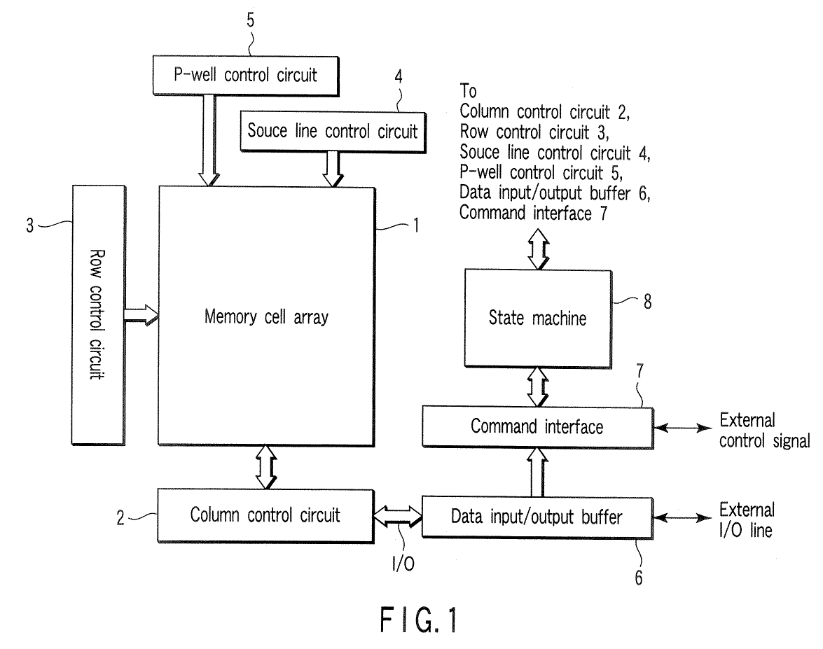

FIG. 1 is a block diagram showing one example of a semiconductor integrated circuit device according to the first embodiment of this invention. As one example of the semiconductor integrated circuit device, the first embodiment shows a NAND flash memory, but this invention can be applied to a memory other than a NAND flash memory.

In a memory cell array 1, nonvolatile semiconductor memory cells are arranged in a matrix form. One example of the nonvolatile semiconductor memory cell is a flash memory cell.

A column control circuit 2 controls the bit lines of the memory cell array 1 and performs the operations of erasing data of the memory cell, writing data into the memory cell and reading data from the memory cell. The column control circuit 2 is arranged adjacent to the memory cell array 1.

A row control circuit 3 selects one of the word lines of the memory cell array 1 and applies a voltage necessary for erasing, writing or reading.

A source line control circuit (C-source control circuit) 4 controls the source lines of the memory cell array 1.

A P-type cell well control circuit (C-p-well control circuit) 5 controls the potential of a P-type well in which the memory cell array 1 is formed.

A data input/output buffer 6 is electrically connected to the column control circuit 2 via an I/O line and electrically connected to an external host (not shown) via an external I/O line. For example, in the data input/output buffer 6, an input/output buffer circuit is arranged. The data input/output buffer 6 receives write data, outputs read data and receives address data and command data. The data input/output buffer 6 supplies received write data to the column control circuit 2 via the I/O line and receives data read from the column control circuit 2 via the I/O line. Further, it supplies externally input address data to the column control circuit 2 and row control circuit 3 via a state machine 8 so as to select the address of the memory cell array 1. Also, it supplies command data from the external host to a command interface 7.

The command interface 7 receives a control signal from the external host via an external control signal line and determines whether data input to the data input/output buffer 6 is write data, command data or address data. Then, it transfers the data as reception command data to the state machine 8 if the data is command data.

The state machine 8 manages the whole portion of the flash memory. It receives command data from the external host and performs the read, write, erase and input/output management processes.

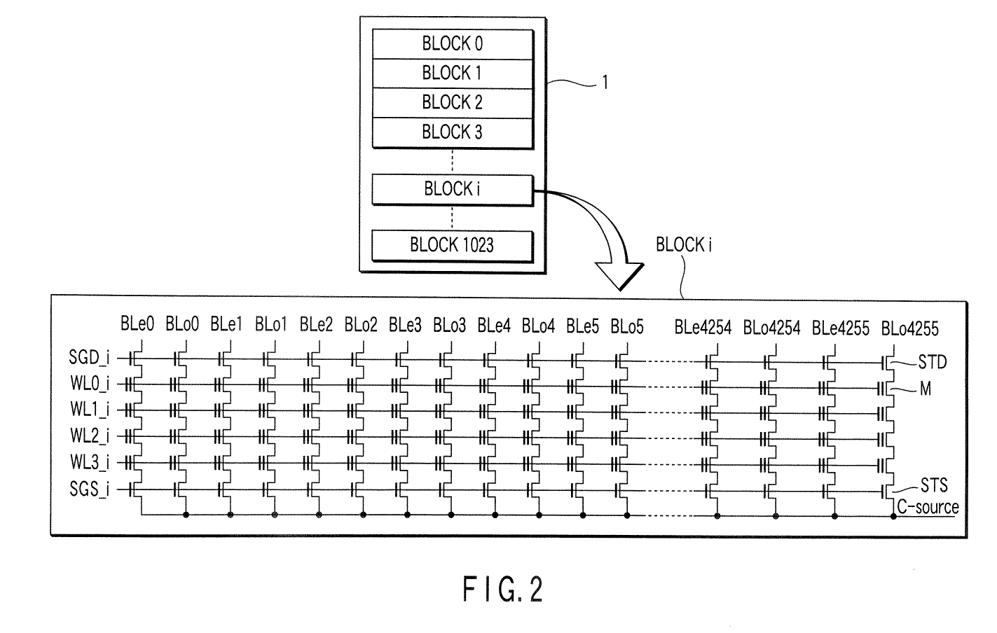

FIG. 2 is a diagram showing one example of the memory cell array 1 shown in FIG. 1.

The memory cell array 1 is divided into a plurality of blocks, for example, 1024 blocks BLOCK0 to BLOCK1023. For example, the block is a minimum unit for erase. Each block BLOCKi includes a plurality of NAND memory units, for example, 8512 NAND memory units. In this example, each NAND memory unit includes two selection transistors STD, STS and a plurality of memory cells M (in this example, four memory cells M) serially connected between the above two transistors. One end of the NAND memory unit is connected to a corresponding one of the bit lines BL via the selection transistor STD whose gate is connected to a selection gate line SGD and the other end thereof is connected to a common C-source line via the selection transistor STS whose gate is connected to a selection gate line SGS. The gate of each memory cell M is connected to a corresponding one of the word lines WL. The data write and read operations for even-numbered bit lines BLe and odd-numbered bit lines BLo counted from “0” are independently performed. The data write or read operations are simultaneously performed for, for example, 4256 memory cells connected to the bit lines BLe among the 8512 memory cells connected to one word line WL. One-bit data is stored in each memory cell M and data items of 4256 memory cells are collected together to configure a unit which is one page. For example, the page is a minimum unit read. When 2-bit data is stored in each memory cell M, the 4256 memory cells store data of two pages. Likewise, the 4256 memory cells connected to the bit lines BLo configure different two pages and the data write or read operations are simultaneously performed for the memory cells of each page.

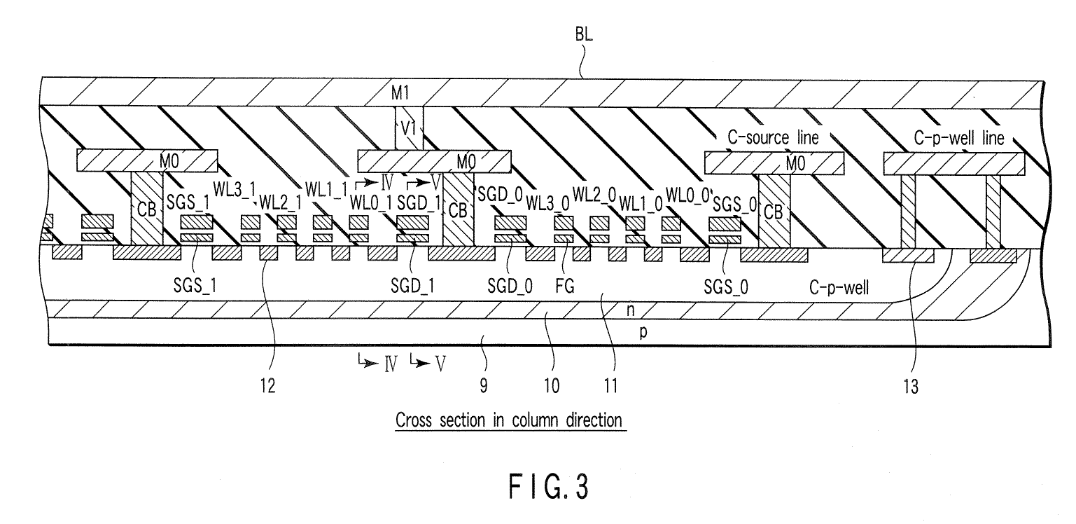

FIG. 3 is a cross-sectional view showing one example of the structure in the column direction of the memory cell array 1 shown in FIG. 1.

An n-type cell well 10 is formed in a p-type semiconductor substrate 9. A p-type cell well 11 is formed in the n-type cell well 10. The memory cell M includes n-type diffusion layers 12 acting as source/drain regions, a floating gate FG, and a control gate acting as the word line WL. The selection gate S (SGS, SGD) includes n-type diffusion layers 12 acting as source/drain regions and a double-structured gate acting as the selection gate SG. The word line WL and selection gate line SG are connected to the row control circuit 3 and controlled by the row control circuit 3.

One end of the NAND memory cell unit is connected to a first metal interconnection layer M0 via a first contact CB and connected to a second metal interconnection layer M1 functioning as the bit line BL via a second contact V1. The bit line BL is connected to the column control circuit 2. The other end of the NAND memory unit is connected to the first metal interconnection layer M0 functioning as the common source line C-source via the first contact hole CB. The common source line C-source is connected to the source line control circuit 4.

The n-type cell well 10 and p-type cell well 11 are set at the same potential and connected to the P well control circuit 5 via the well line C-p-well.

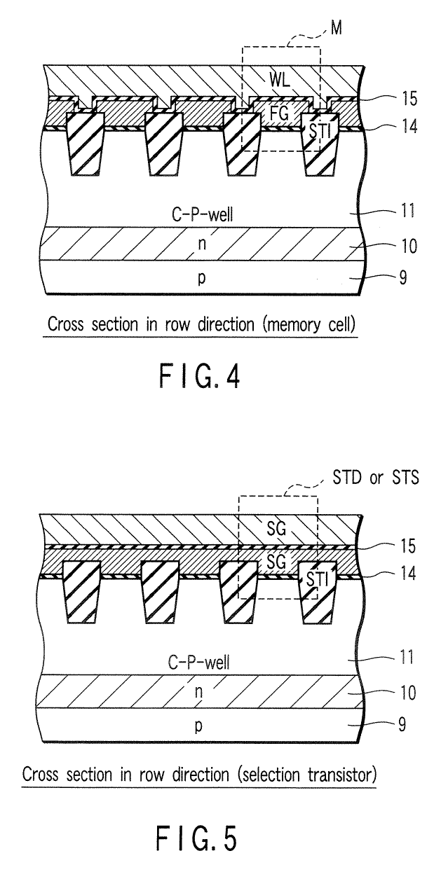

FIGS. 4 and 5 are cross-sectional views showing one example of the structure in the row direction of the memory cell array 1 shown in FIG. 1.

As shown in FIG. 4, the memory cells M are isolated by use of element isolation regions STI. The floating gate FG is stacked on a channel region with a tunnel oxide film 14 disposed therebetween. The word line WL is stacked on the floating gate FG with an ONO film 15 disposed therebetween.

As shown in FIG. 5, the selection gate line SG has a double structure. Although not shown in the drawing, the upper and lower selection gate lines SG are connected to one end of the memory cell array 1 or to the bit lines for every preset number.

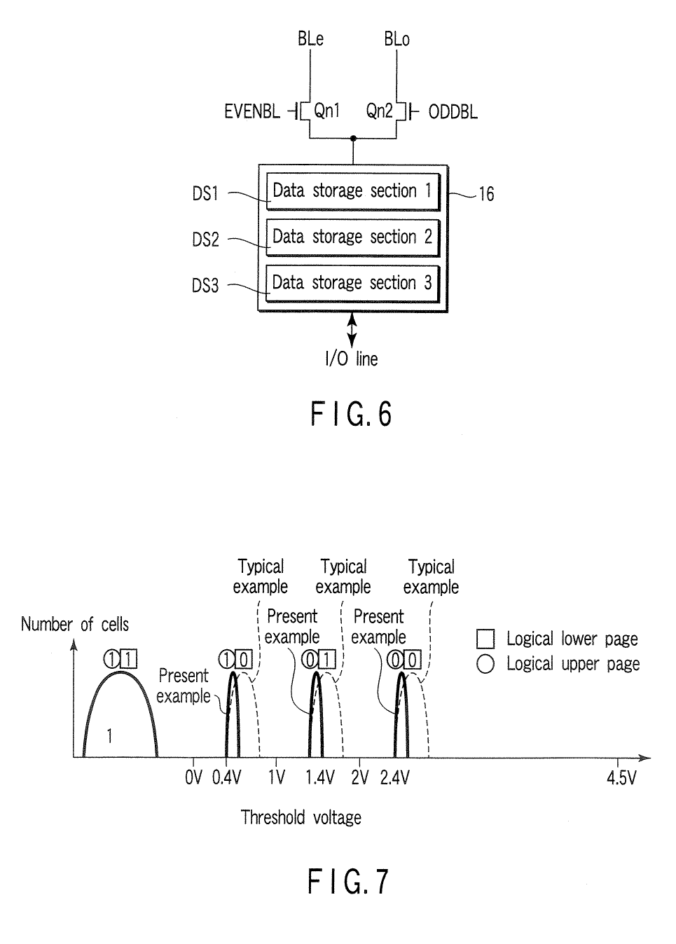

FIG. 6 is a block diagram showing one example of the column control circuit 2 shown in FIG. 1.

Each data storage circuit 16 is provided for every two bit lines (for example, BLe5 and BLo5) of the even-numbered bit line BLe and odd-numbered bit line BLo having the same column number. One of the bit lines BLe and BLo is selected and connected to the data storage circuit 16. Then, the potential of the bit line BLe or BLo is controlled for data write or readout. When a signal EVENBL is made high (“H” level) and a signal ODDBL is made low (“L” level), the bit line BLe is selected. The bit line BLe is connected to the data storage circuit 16 via an n-channel MOS transistor Qn1. On the other hand, when the signal EVENBL is made low and the signal ODDBL is made high, the bit line BLo is selected. The bit line BLo is connected to the data storage circuit 16 via an n-channel MOS transistor Qn2. The signal EVENBL is common for all of the even-numbered bit lines BLe. Likewise, the signal ODDBL is common for all of the odd-numbered bit lines BLo. The non-selected bit lines are controlled by a circuit (not shown).

The data storage circuit 16 includes three binary data storage sections DS1, DS2, DS3. The data storage section DS1 is connected to the data input/output buffer 6 via the data input/output line (I/O line) and stores externally write data input or read data to be externally output. The data storage section DS2 stores a detection result at the time of recognition (write verify) of the threshold voltage of the memory cell M after writing. The data storage section DS3 temporarily stores data of the memory cell M at the write time and read time.

FIG. 7 is a diagram showing the relation between multi-level data of a multi-level flash memory and the threshold voltage of the memory cell M.

In this example, 2-bit data is stored in one memory cell M. As the 2-bit data, “11”, “10”, “00”, “01” are used. The two bits belong to different row addresses (different pages).

After erasing, data of the memory cell M is set to “11”. If lower page data with respect to the memory cell M is “0”, the state is changed from “11” to “10” by writing. When “1” data is written, the state “11” is kept unchanged.

Next, upper page data is written. If data is “1”, the state of “11” or “10” is maintained. If data is “0”, the state of “11” is changed to “01” and the state “10” is changed to “00”.

If the threshold voltage is lower than 0V, for example, the state is regarded as “11”, and if the threshold voltage is equal to or higher than 0V and lower than 1V, for example, the state is regarded as “10”. Further, if the threshold voltage is equal to or higher than 1V and lower than 2V, for example, the state is regarded as “01” and if the threshold voltage is equal to or higher than 2V, for example, the state is regarded as “00”.

Thus, four threshold voltages are used in order to store 2-bit data in one memory cell. In the actual device, since a variation occurs in the characteristics of the memory cells, the threshold voltages thereof also vary. If the variation is large, data cannot be distinguished and erroneous data may be read.

In the write method according to the present embodiment, first, variations in the typical threshold voltages as indicated by broken lines can be suppressed to narrow ranges as indicated by solid lines.

Tables 1 and 2 indicate voltages in the respective portions at the erase time, write time, read time and write verify time. In the tables 1 and 2, a case wherein the word line WL2 and the even-numbered bit line BLe are selected at the write time and read time is shown.

TABLE 1

| | | First-step | Second-step | Write | “10” | “01” | “00” |
|---|---|---|---|---|---|---|---|
| | Erase | Write | Write | Inhibition | Read | Read | Read |
| BLe | Floating | 0 V | 0.4 V | Vdd | H or L | H or L | H or L |
| BLo | Floating | Vdd | Vdd | Vdd | 0 V | 0 V | 0 V |
| SGD | Floating | Vdd | Vdd | Vdd | 4.5 V | 4.5 V | 4.5 V |
| WL3 | 0 V | 10 V | 10 V | 10 V | 4.5 V | 4.5 V | 4.5 V |
| WL2 | 0 V | Vpgm | Vpgm | Vpgm | 0 V | 1 V | 2 V |
| WL1 | 0 V | 0 V | 0 V | 0 V | 4.5 V | 4.5 V | 4.5 V |
| WL0 | 0 V | 10 V | 10 V | 10 V | 4.5 V | 4.5 V | 4.5 V |
| SGS | Floating | 0 V | 0 V | 0 V | 4.5 V | 4.5 V | 4.5 V |
| C-source | Floating | 0 V | 0 V | 0 V | 0 V | 0 V | 0 V |
| C-p-well | 20 V | 0 V | 0 V | 0 V | 0 V | 0 V | 0 V |

TABLE 2

| | “10” | “10” | “01” | “01” | “00” | “00” |
|---|---|---|---|---|---|---|
| | First-step | Second-step | First-step | Second-step | First-step | Second-step |
| | Write Verify | Write Verify | Write Verify | Write Verify | Write Verify | Write Verify |
| BLe | H or L | H or L | H or L | H or L | H or L | H or L |
| BLo | 0 V | 0 V | 0 V | 0 V | 0 V | 0 V |
| SGD | 4.5 V | 4.5 V | 4.5 V | 4.5 V | 4.5 V | 4.5 V |
| WL3 | 4.5 V | 4.5 V | 4.5 V | 4.5 V | 4.5 V | 4.5 V |
| WL2 | 0.2 V | 0.4 V | 1.2 V | 1.4 V | 2.2 V | 2.4 V |
| WL1 | 4.5 V | 4.5 V | 4.5 V | 4.5 V | 4.5 V | 4.5 V |
| WL0 | 4.5 V | 4.5 V | 4.5 V | 4.5 V | 4.5 V | 4.5 V |
| SGS | 4.5 V | 4.5 V | 4.5 V | 4.5 V | 4.5 V | 4.5 V |
| C-source | 0 V | 0 V | 0 V | 0 V | 0 V | 0 V |
| C-p-well | 0 V | 0 V | 0 V | 0 V | 0 V | 0 V |

(Erase)

At the erase time, the p-type cell well (C-p-well) 11 is set to 20V and all of the word lines WL0 to WL3 of a selected block are set to 0V. Electrons are discharged from the floating gate and the threshold voltage of the memory cell M is set to a negative voltage (“11” state). In this case, the word lines WL and bit lines BL of the non-selected block are set into an electrically floating state and set to approximately 20V due to the capacitive coupling with the p-type cell well 11.

(Write)

At the write time, the voltage Vpgm of 14V to 20V is applied to the selected word line WL2. In this state, if the selected bit line BLe is set to 0V, electrons are injected into the floating gate FG to rapidly raise the threshold voltage of the memory cell M (first-step write). In order to suppress the rising speed of the threshold voltage, the potential of the bit line BLe is raised t 0.4V (second-step write). In order to inhibit the rise in the threshold voltage, the potential of the bit line BLe is set to power supply voltage Vdd (about 3V) (write inhibition).

(Read)

At the read time, read voltage (0V, 1V, 2V) is applied to the selected word line WL2. If the threshold voltage of the memory cell M is lower than the read voltage, for example, the bit line BLe and common source line C-source are electrically connected to each other and the potential of the bit line BLe is set to the relatively low level “L”. If the threshold voltage of the memory cell M is equal to or higher than the read voltage, for example, the bit line BLe and common source line C-source are isolated from each other and the potential of the bit line BLe maintains the relatively high level “H”. In order to detect whether or not the threshold voltage of the memory cell M is set higher than the state “10”, the read voltage is set to 0V (“10” read). In order to detect whether or not the threshold voltage of the memory cell M is set higher than the state “01”, the read voltage is set to 1V (“01” read). In order to detect whether or not the threshold voltage of the memory cell M is set higher than the state “00”, the read voltage is set to 2V (“00” read).

The threshold voltage in the “10” state is set equal to or higher than 0.4V so as to provide a read margin of 0.4V with respect to the read voltage 0V. For this purpose, in the case of writing “10”, a write verify operation is performed and if it is detected that the threshold voltage of the memory cell M has reached 0.4V, a write inhibiting operation is performed to control the threshold voltage. Typically, in this case, only whether or not the threshold voltage has reached 0.4V is detected. Therefore, as shown in FIG. 7, a relatively wide threshold voltage distribution range is provided (typical example).

On the other hand, in this example, whether the threshold voltage which is slightly lower than a target threshold voltage is reached or not is detected and the rising speed of the threshold voltage is suppressed in the second-step write process to narrow the threshold voltage distribution width as shown in FIG. 7 (in this example). This applies to the other states “01” and “00”.

The write verifying operation is performed by applying a verify voltage (0.2V, 0.4V, 1.2V, 1.4V, 2.2V, 2.4V) to the selected word line WL2. For example, if the threshold voltage of the memory cell M is lower than the verify voltage, the bit line BLe and common source line C-source are electrically connected to each other and the potential of the bit line BLe is set to the relatively low level “L”. For example, if the threshold voltage of the memory cell M is equal to or higher than the verify voltage, the bit line BLe and common source line C-source are isolated from each other and the potential of the bit line BLe maintains the relatively high level “H”. In order to detect whether or not the threshold voltage of the memory cell M is higher than 0.2V, the write verify process is performed with the verify voltage set at 0.2V (“10” first-step write verify). In order to detect whether or not the threshold voltage of the memory cell M is higher than 0.4V, the write verify process is performed with the verify voltage set at 0.4V (“10” second-step write verify). In order to detect whether or not the threshold voltage of the memory cell M is higher than 1.2V, the write verify process is performed with the verify voltage set at 1.2V (“01” first-step write verify). In order to detect whether or not the threshold voltage of the memory cell M is higher than 1.4V, the write verify process is performed with the verify voltage set at 1.4V (“01” second-step write verify). In order to detect whether or not the threshold voltage of the memory cell M is higher than 2.2V, the write verify process is performed with the verify voltage set at 2.2V (“00” first-step write verify). In order to detect whether or not the threshold voltage of the memory cell M is higher than 2.4V, the write verify process is performed with the verify voltage set at 2.4V (“00” second-step write verify).

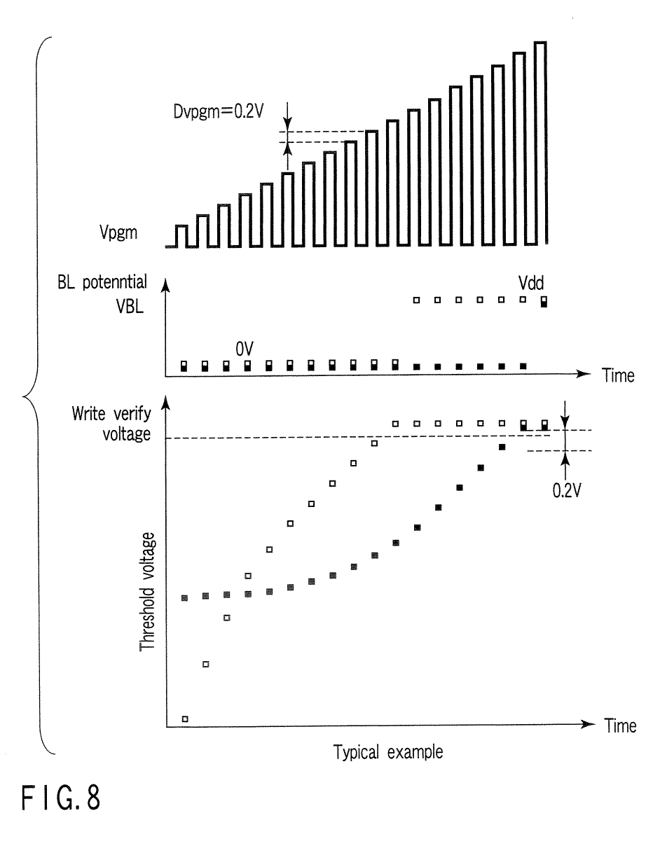

FIG. 8 is a diagram showing a typical write method and threshold voltage control process.

In FIG. 8, each void square indicates the threshold voltage of a memory cell into which data can be easily written and each black square indicates the threshold voltage of a memory cell into which data is difficult to be written. The above two memory cells store data items of the same page. Each of them is initially set in the erase state and has a negative threshold voltage.

As shown in FIG. 8, the write voltage Vpgm is divided into a plurality of pulses and is raised by 0.2V for each pulse (Dvpgm=0.2V), for example. If the voltage of the bit line BL which is the write control voltage is set to 0V, the threshold voltage is raised at the same rate of 0.2 V/pulse as the voltage rise rate of the write voltage Vpgm after several pulses. The write verify process is performed after application of each write pulse, the bit line voltage of a memory cell whose threshold voltage has reached the write verify voltage is set to Vdd, and the write process is inhibited for each memory cell. Thus, the threshold voltage has the distribution width of 0.2V.

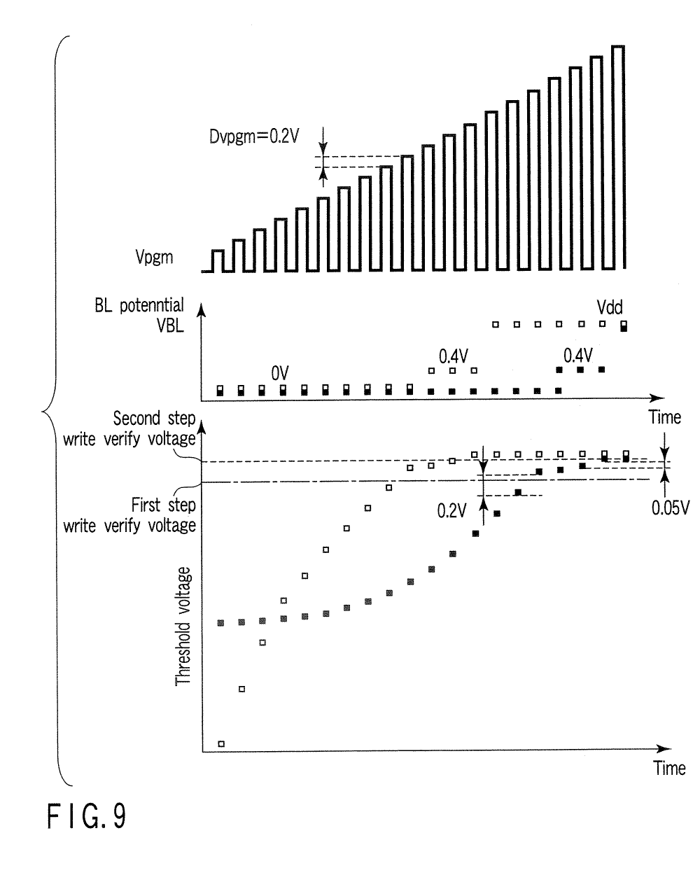

FIG. 9 is a diagram showing the write method of this example and threshold control process.

In FIG. 9, each void square indicates the threshold voltage of a memory cell into which data can be easily written and each black square indicates the threshold voltage of a memory cell into which data is difficult to be written. The above two memory cells store data items of the same page. Each of them is initially set in the erase state and has a negative threshold voltage.

As shown in FIG. 9, the write voltage Vpgm is divided into a plurality of pulses and is raised by 0.2V for each pulse (Dvpgm=0.2V), for example. If the voltage of the bit line BL which is the write control voltage is set to 0V, the first-step write process is performed and the threshold voltage is raised at the same rate of 0.2 V/pulse as the voltage rise rate of the write voltage Vpgm after several pulses. The first-step and second-step write verify processes are performed after application of each write pulse, the bit line voltage of a memory cell whose threshold voltage has reached the first-step write verify voltage is set to 0.4V, and the second-step write process is performed for each memory cell. Further, the bit line voltage of a memory cell whose threshold voltage has reached the second-step write verify voltage is set to Vdd and the write process is inhibited for each memory cell. Since the rise rate of the threshold voltage is suppressed to approximately 0 V/pulse to 0.05 V/pulse, for example, for several pulses after the second-step write process is started, the threshold voltage only has the distribution width of 0.05V. Thus, the threshold voltage distribution width can be narrowed.

If the write pulse width is set to 20 μsec and each write verify time is set to 5 μsec, the write time produced by the typical write method is expressed as follows.
(20 μsec+5 μsec)×18 pulses=450 μsec

However, since it is necessary to reduce the voltage rise rate of the write voltage Vpgm to 0.05V, that is, one-fourth in order to realize the threshold voltage distribution of 0.05V, the write time becomes as follows.
450 μsec×4=1800 μsec

According to this example, as shown in FIG. 9, the threshold voltage distribution width of 0.05V can be realized with the Vpgm rise rate of 0.2 V/pulse and the write time becomes as follows.
(20 μsec+5 μsec+5 μsec)×20 pulses=600 μsec

That is, in this example, the write time required for realizing the threshold voltage distribution of 0.05V, which is the same as in the typical write method, can be reduced to one-third in comparison with the typical write method.

In this case, a “10” write process is performed by setting the first-step write verify voltage to the “10” first-step write verify voltage and setting the second-step write verify voltage to the “10” second-step write verify voltage.

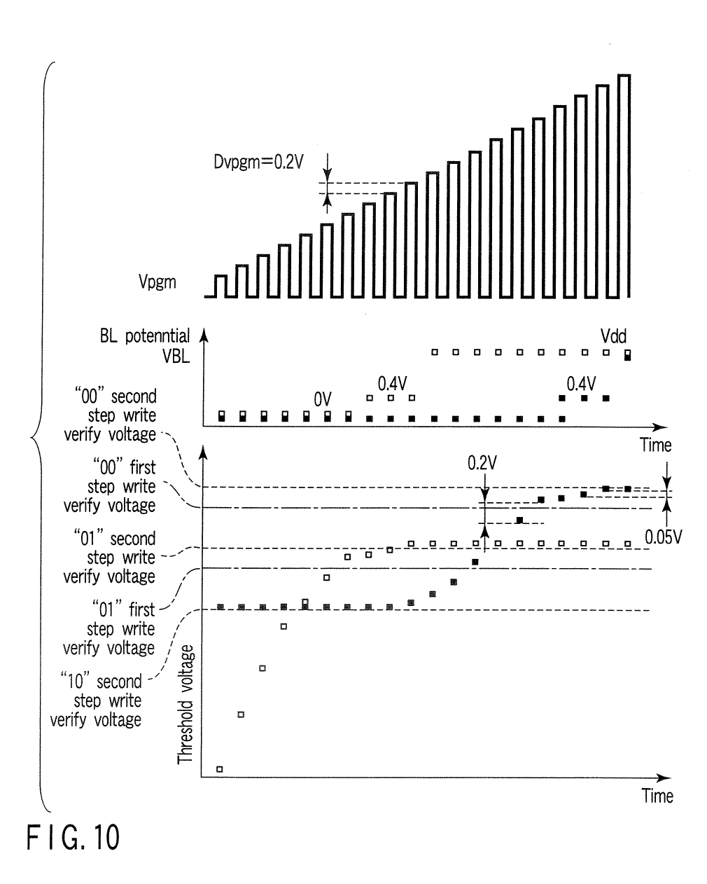

FIG. 10 is a diagram showing a method of writing upper page data into the same memory cell M in this example and a threshold control operation.

In FIG. 10, each void square indicates the threshold voltage of a memory cell into which data can be easily written and each black square indicates the threshold voltage of a memory cell into which data is difficult to be written. The above two memory cells store data items of respective columns of the same page. The memory cell indicated by the void square is initially set in the erase state, has a negative threshold voltage and is written into a “0l” state. The memory cell indicated by the black square is initially set in the “10” state and is written into a “00” state.

As shown in FIG. 10, the write voltage Vpgm is divided into a plurality of pulses and is raised by 0.2V for each pulse (Dvpgm=0.2V), for example. If the voltage of the bit line BL which is the write control voltage is set to 0V, the first-step write process is performed and the threshold voltage is raised at a rate of 0.2 V/pulse which is the same as the voltage rise rate of the write voltage Vpgm after several pulses. The “01” first-step and “01” second-step write verify processes are performed after application of each write pulse and then the “00” first-step and “00” second-step write processes are performed.

When it is detected that the threshold voltage of the memory cell indicated by the void square has reached the “01” first-step write verify voltage, the bit line voltage is set to 0.4V and the second-step write state is set up. When it is detected that the threshold voltage of the memory cell indicated by the black square has reached the “00” first-step write verify voltage, the bit line voltage is set to 0.4V and the second-step write state is set up.

When it is detected that the threshold voltage of the memory cell indicated by the void square has reached the “01” second-step write verify voltage, the bit line voltage is set to Vdd and the write operation is inhibited. Further, when it is detected that the threshold voltage of the memory cell indicated by the black square has reached the “00” second-step write verify voltage, the bit line voltage is set to Vdd and the write operation is inhibited.

For both of “01” and “00”, since the rise rate of the threshold voltage is suppressed to approximately 0 V/pulse to 0.05 V/pulse for a time period of several pulses after the second-step write state is set up, for example, the threshold voltage has only the distribution width of 0.05V.

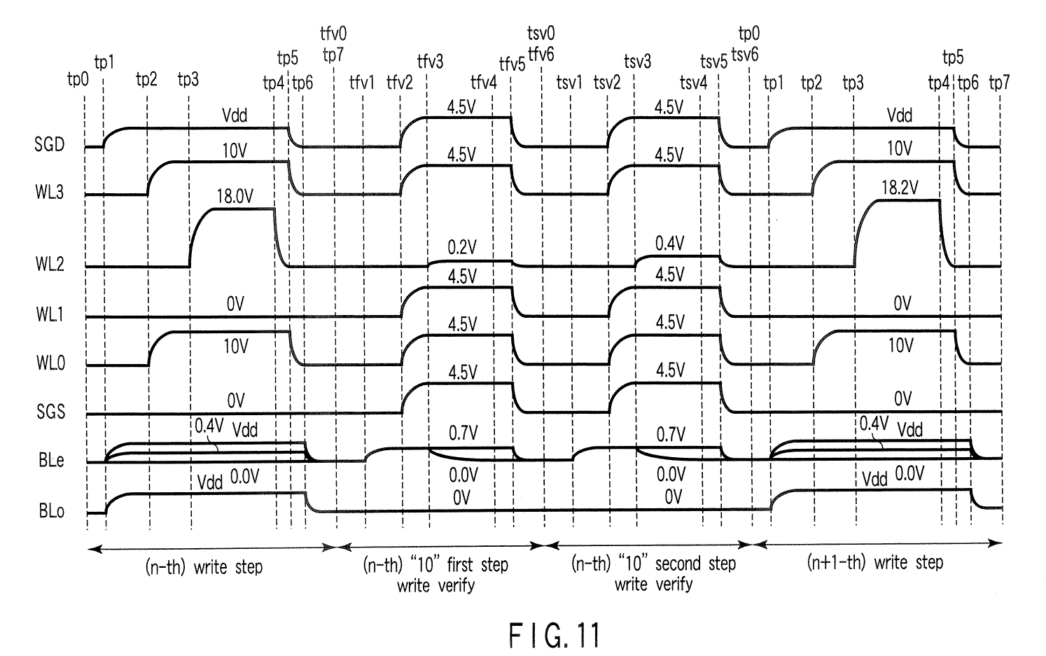

FIG. 11 is an operation waveform diagram showing waveforms at the write time of lower page data into the same memory cell M.

The write step is performed in a period from time tp0 to tp7 and a write pulse is applied. The “10” first-step write verify operation is performed in a period from time tfv0 to tfv6 and the “10” second-step write verify operation is performed in a period from time tsv0 to tsv6. In this example, a case wherein the word line WL and the even-numbered bit line BLe are selected is shown.

In the write step, the voltage of the bit line BLe which is the write control voltage is set to 0V in the first-step write state, 0.4V in the second-step write state and Vdd (for example, 2.5V) in the write inhibition state.

At each write verify time, first, the bit line BLe is charged to 0.7V. After this, when the voltage of the selected word line WL2 has reached the write verify voltage, the voltage of 0.7V is maintained if the threshold voltage of the memory cell M has reached the write verify voltage. In this case, the voltage is lowered towards 0V if the threshold voltage of the memory cell M does not reach the write verify voltage.

If the voltage of the bit line BLe is detected at the timing of time tfv4 or tsv4, whether or not the threshold voltage of the memory cell M has reached the write verify voltage can be detected. If the threshold voltage of the memory cell M has reached the write verify voltage, the detection result is “pass”.

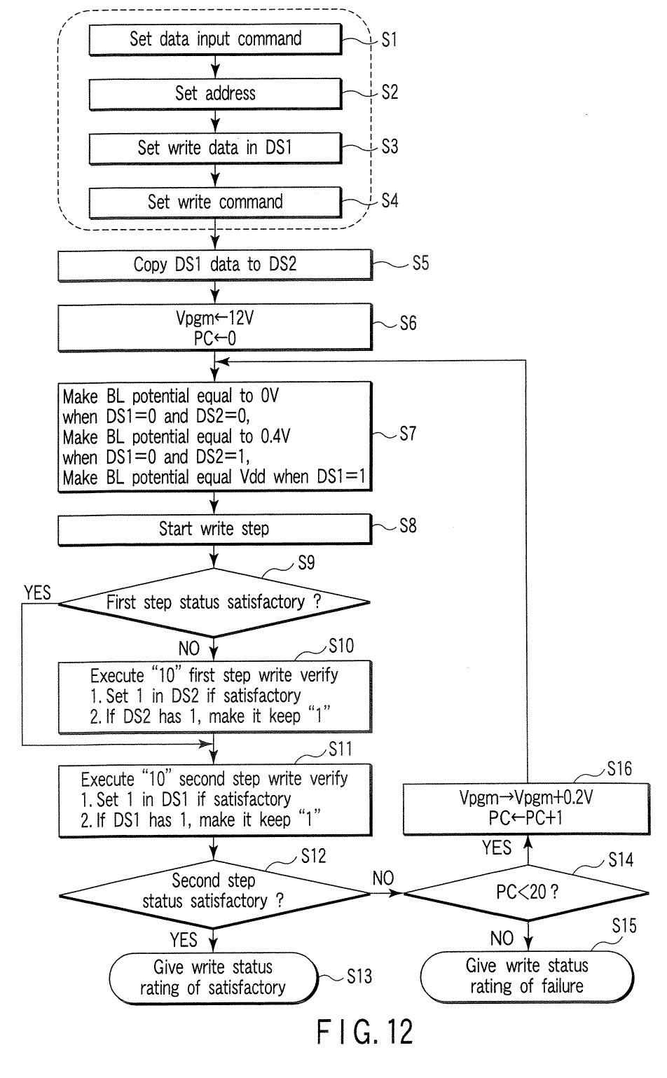

FIG. 12 is a flow chart showing an algorithm of writing lower page data into the same memory cell M.

First, for example, the command interface 7 receives a data input command from the host and sets the data input command in the state machine 8 (S1).

Next, for example, the command interface 7 receives address data from the host and sets an address to select a write page in the state machine 8 (S2).

Next, for example, the data input/output buffer 6 receives write data of one page and sets corresponding write data into the respective data storage sections DS1 (S3).

Next, for example, the command interface 7 receives a write command issued from the host and sets the write command in the state machine 8 (S4). After the write command is set, the steps S5 to S16 are automatically started in the internal portion by the state machine 8.

Next, data of each data storage section DS1 is copied into a corresponding one of the data storage sections DS2 (S5). After this, the initial value of the write voltage Vpgm is set to 12V and the write counter PC is set to “0” (S6).

If data of the data storage section DS1 is “0” and data of the data storage section DS2 is “0”, it is determined that the first-step write state is set. Therefore, the voltage of the bit line which is the write control voltage is set at 0V.

If data of the data storage section DS1 is “0” and data of the data storage section DS2 is “1”, it is determined that the second-step write state is set. Therefore, the voltage of the bit line which is the write control voltage is set at 0.4V.

If data of the data storage section DS1 is “1”, it is determined that the write inhibition state is set. Therefore, the voltage of the bit line which is the write control voltage is set at Vdd (S7).

Next, write pulses are applied to the memory cells of one page by use of the set write voltage Vpgm and write control voltage. That is, the write step is performed (S8).

Whether or not data items of all of the data storage sections DS2 are “1” is detected and if all of the data items are “1”, it is determined that the first-step status is “pass”, and if not, it is determined that the above status is not “pass” (S9). As will be described later, if data items of all of the data storage sections DS2 are “1”, it is determined that no memory cell is subjected to the first-step write operation in the preceding write step (S8).

If the first-step status is not “pass”, the “10” first-step write verify operation is started (S10). Data of the data storage section DS2 corresponding to the memory cell in which the detection result is set to “pass” among the memory cells of one page is changed from “0” to “1”. If data of the data storage section DS2 is “1”, the “1” data is maintained.

If the first-step status is “pass” or when the “10” first-step write verify operation is terminated, the “10” second-step write verify operation is started (S11). Data of the data storage section DS1 corresponding to the memory cell in which the detection result is set to “pass” among the memory cells of one page is changed from “0” to “1”. If data of the data storage section DS1 is “1”, the “1” data is maintained.

After the “10” second-step write verify operation, whether or not data items of all of the data storage sections DS1 are “1” is detected and if all of the data items are “1”, it is determined that the second-step status is “pass”, and if not, it is determined that the above status is not “pass” (S12).

If the second-step status is “pass”, it is determined that the write operation is correctly terminated, the write status is set to “pass” and the write operation is terminated (S13).

If the second-step status is not “pass”, the write counter PC is checked (S14) and if the count thereof is equal to or larger than 20, it is determined that data could not be correctly written, the write status is set to “fail” and the write operation is terminated (S15).

If the count of the write counter PC is smaller than 20, the count of the write counter PC is incremented by one, the setting value of the write voltage Vpgm is increased by 0.2V (S16) and the process is returned to the write step S8 again after the step S7 is performed.

Table 3 shows the relation between data items before and after the “10” first-step write verify operation of the data storage sections DS1 and DS2 in the algorithm of writing lower page data into the same memory cell M shown in FIG. 12 and the threshold voltage of a corresponding memory cell.

TABLE 3

| | | Threshold voltage Vt of memory cell | |
|---|---|---|---|
| | | Lower than 0.2 V | Not lower than 0.2 V |
| Data DS1/DS2 | 0/0 | 0/0 | 0/0 |
| before nth “10” | 0/1 | 0/1 | 0/1 |
| first-step | 1/1 | 1/1 | 1/1 |
| write verify | | | |

Data DS1/DS2 after the nth “10” first-step write verify

As shown in table 3, a value which can be set in the data storage sections DS1 and DS2 before the nth “10” first-step write verify operation is 0/0, 0/1 or 1/1.

0/0 indicates that the threshold voltage of the memory cell does not reach the “10” first-step write verify voltage until the (n-l)th write step.

0/1 indicates that the threshold voltage of the memory cell has reached the “10” first-step write verify voltage, but does not reach the “10” second-step write verify voltage until the (n-1)th write step.

1/1 indicates that the threshold voltage of the memory cell has reached the “10” second-step write verify voltage until the (n-1)th write step.

Since there occurs no possibility that the threshold voltage of the memory cell has reached the “10” second-step write verify voltage, but does not reach the “10” first-step write verify voltage until the (n-1)th write step, the state of 1/0 is not provided in this example.

A value which can be set in the data storage sections DS1 and DS2 before the first “10” first-step write verify operation is 0/0 or 1/1.

Since the detection result in the “10” first-step write verify operation is not “pass” if the threshold voltage of the memory cell does not reach 0.2V which is the “10” first-step write verify voltage in the nth write step, data of the data storage section DS2 is kept unchanged. Since the detection result in the “10” first-step write verify operation is “pass” if the threshold voltage of the memory cell reaches 0.2V which is the “10” first-step write verify voltage in the nth write step, data of the data storage section DS2 is changed to “1”. Data of the data storage section DS2 which is “1” is kept unchanged irrespective of the threshold voltage of the memory cell.

Table 4 shows the relation between data items before and after the “10” second-step write verify operation of the data storage sections DS1 and DS2 in the algorithm of writing lower page data into the same memory cell M shown in FIG. 12 and the threshold voltage of a corresponding memory cell.

TABLE 4

| | | Threshold voltage Vt of memory cell | |
|---|---|---|---|
| | | Lower than 0.4 V | Not lower than 0.4 V |
| Data DS1/DS2 | 0/0 | 0/0 | — |
| before nth “10” | 0/1 | 0/1 | 1/1 |
| second-step | 1/1 | 1/1 | 1/1 |
| write verify | | | |

Data DS1/DS2 after the nth “10” second-step write verify

As shown in table 4, a value which can be set in the data storage sections DS1 and DS2 before the nth “10” second-step write verify operation is 0/0, 0/1 or 1/1.

0/0 indicates that the threshold voltage of the memory cell does not reach the “10” first-step write verify voltage after the nth write step. 0/1 indicates that the threshold voltage of the memory cell has reached the “10” first-step write verify voltage until the nth write step, but the threshold voltage of the memory cell does not reach the “10” second-step write verify voltage until the (n-1)th write step. 1/1 indicates that the threshold voltage of the memory cell has reached the “10” second-step write verify voltage until the (n-1)th write step.

Since there occurs no possibility that the threshold voltage of the memory cell has reached the “10” second-step write verify voltage until the (n-1)th write step, but the threshold voltage of the memory cell does not reach the “10” first-step write verify voltage until the nth write step, the state of 1/0 is not provided in this example.

Since the detection result in the “10” second-step write verify operation is not “pass” if the threshold voltage of the memory cell does not reach 0.4V, which is the “10” second-step write verify voltage in the nth write step, data of the data storage section DS1 is kept unchanged. Since the detection result in the “10” second-step write verify operation is “pass” if the threshold voltage of the memory cell reaches 0.4V which is the “10” second-step write verify voltage in the nth write step, data of the data storage section DS1 is changed to “1”. Data of the data storage section DS1 which is “1” is kept unchanged irrespective of the threshold voltage of the memory cell. 0/0 is not changed by the “10” second-step write verify operation.

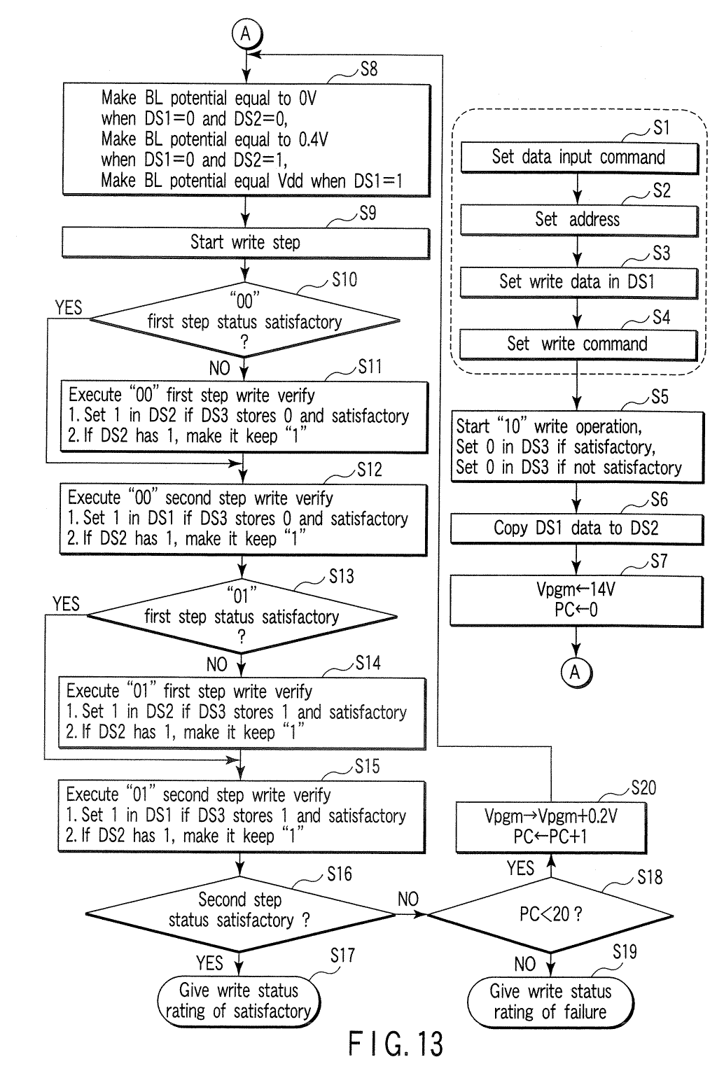

FIG. 13 is a diagram showing a write algorithm of upper page data to the same memory cell M.

First, for example, the command interface 7 receives a data input command from the host and sets the data input command in the state machine 8 (S1).

Next, for example, the command interface 7 receives address data from the host and sets an address to select a write page in the state machine 8 (S2).

Then, for example, the data input/output buffer 6 receives write data of one page and sets corresponding write data into the respective data storage sections DS1 (S3).

Next, for example, the command interface 7 receives a write command issued from the host and sets the write command in the state machine 8 (S4). After the write command is set, steps S5 to S20 are automatically started in the internal portion by the state machine 8.

First, the “10” read operation is started (S5). In the case of “pass” (when the memory cell is “10”), “0” is set into a corresponding one of the data storage sections DS3. If it is not “pass”, “1” is set into a corresponding one of the data storage sections DS3.

Next, data of each data storage section DS1 is copied into a corresponding one of the data storage sections DS2 (S6). After this, the initial value of the write voltage Vpgm is set to 14V and the write counter PC is set to “0” (S7).

If data of the data storage section DS1 is “0” and data of the data storage section DS2 is “0”, it is determined that the first-step write state is set. Therefore, the voltage of the bit line which is the write control voltage is set at 0V.

If data of the data storage section DS1 is “0” and data of the data storage section DS2 is “1”, it is determined that the second-step write state is set. Therefore, the voltage of the bit line which is the write control voltage is set at 0.4V.

If data of the data storage section DS1 is “1”, it is determined that the write inhibition state is set. Therefore, the voltage of the bit line which is the write control voltage is set at Vdd (S8).

Next, write pulses are applied to the memory cells of one page by use of the set write voltage Vpgm and write control voltage. That is, the write step is performed (S9).

Whether or not data items of all of the data storage sections DS2 in the data storage circuit 16 in which “0” is stored in the data storage section DS3 are “1” is detected. Then, if all of the data items are “1”, it is determined that the “00” first-step status is “pass”, and if not, it is determined that the above status is not “pass” (S10). As will be described later, if data items of all of the data storage sections DS2 are “1”, there is no memory cell which is subjected to the “00” first-step write operation in the preceding write step (S9).

If the “00” first-step status is not “pass”, the “00” first-step write verify operation is started (S11). Data of the data storage section DS2 corresponding to the memory cell in which the detection result is set to “pass” among the memory cells of one page and lying in the data storage circuit 16 in which data of the data storage section DS3 is “0” is changed from “0” to “1”. If data of the data storage section DS2 is “1”, the “1” data is maintained.

If the “00” first-step status is “pass” or when the “00” first-step write verify operation is terminated, the “00” second-step write verify operation is started (S12). Data of the data storage section DS1 corresponding to the memory cell in which the detection result is set to “pass” among the memory cells of one page and lying in the data storage circuit 16 in which data of the data storage section DS3 is “0” is changed from “0” to “1”. If data of the data storage section DS1 is “1”, the “1” data is maintained.

Next, whether data items of all of the data storage sections DS2 in the data storage circuit 16 in which data “1” is stored in the data storage section DS3 are “1” or not is detected. Then, if all of the data items are “1” it is determined that the “01” first-step status is “pass”, and if not, it is determined that the above status is not “pass” (S13). As will be described later, if data items of all of the data storage sections DS2 are “1”, there is no memory cell which is subjected to the “01” first-step write operation in the preceding write step (S9).

If the “01” first-step status is not “pass”, the “01” first-step write verify operation is started (S14). Data of the data storage section DS2 corresponding to the memory cell in which the detection result is set to “pass” among the memory cells of one page and lying in the data storage circuit 16 in which data of the data storage section DS3 is “1” is changed from “0” to “1”. If data of the data storage section DS2 is “1”, the “1” data is maintained.

If the “01” first-step status is set to “pass” or the “01” write verify operation is terminated, the “01” second-step write verify operation is started (S15). Data of the data storage section DS1 corresponding to the memory cell in which the detection result is set to “pass” among the memory cells of one page and lying in the data storage circuit 16 in which data of the data storage section DS3 is “1” is changed from “0” to “1”. If data of the data storage section DS1 is “1”, the “1” data is maintained.

After the “01” second-step write verify operation, whether or not data items of all of the data storage sections DS1 are “1” is detected. Then, if all of the data items are “1”, it is determined that the second-step status is “pass”, and if not, it is determined that the above status is not “pass” (S16). If the second-step status is “pass”, it is determined that the write operation is correctly performed, the write status is set to “pass” and the write operation is terminated (S17). If the second-step status is not “pass”, the write counter PC is checked (S18). Then, if the count thereof is not smaller than 20, it is determined that the write operation could not be correctly performed, the write status is set to “fail” and the write operation is terminated (S19). If the count of the write counter PC is smaller than 20, the count of the write counter PC is incremented by one, the setting value of the write voltage Vpgm is increased by 0.2V (S20) and the process is returned to the write step S9 again after the step S8 is performed.

Table 5 shows the relation between data items before and after the “01” first-step write verify operation of the data storage sections DS1, DS2 and DS3 in the algorithm of writing upper page data to the same memory cell M shown in FIG. 12 and the threshold voltage of a corresponding memory cell.

TABLE 5

| | | Threshold voltage Vt of memory cell | |
|---|---|---|---|
| | | Lower than 1.2 V | Not lower than 1.2 V |
| Data DS1/DS2/DS3 | 0/0/1 | 0/0/1 | 0/1/1 |
| before nth “01” | 0/1/1 | 0/1/1 | 0/1/1 |
| first-step | 1/1/1 | 1/1/1 | 1/1/1 |
| write verify | 0/0/0 | 0/0/0 | 0/0/0 |
| | 0/1/0 | 0/1/0 | 0/1/0 |
| | 1/1/0 | 1/1/0 | 1/1/0 |

Data DS1/DS2/DS3 after the nth “01” first-step write verify

As shown in table 5, a value which can be set in the data storage sections DS1, DS2 and DS3 before the nth “01” first-step write verify operation is 0/0/1, 0/1/1, 1/1/1, 0/0/0, 0/1/0 or 1/1/0.

0/0/1 indicates that the threshold voltage of the memory cell does not reach the “01” first-step write verify voltage until the (n-1)th write step.

0/1/1 indicates that the threshold voltage of the memory cell has reached the “01” first-step write verify voltage, but does not reach the “01” second-step write verify voltage until the (n-1)th write step.

1/1/1 indicates that the threshold voltage of the memory cell has reached the “01” second-step write verify voltage until the (n-1)th write step.

Since there occurs no possibility that the threshold voltage of the memory cell has reached the “01” second-step write verify voltage, but does not reach the “01” first-step write verify voltage until the (n-1)th write step, the state of 1/0/1 is not provided in this example.

The detection result in the “01” first-step write verify operation is not “pass” if the threshold voltage of the memory cell does not reach 1.2V which is the “01” first-step write verify voltage in the nth write step. In this case, data of the data storage section DS2 is kept unchanged.

The detection result in the “01” first-step write verify operation is “pass” if the threshold voltage of the memory cell has reached 1.2V which is the “01” first-step write verify voltage in the nth write step. In this case, data of the data storage section DS2 is changed to “1”. Data of the data storage section DS2 which is “1” is kept unchanged irrespective of the threshold voltage of the memory cell. Further, 0/0/0, 0/1/0, 1/1/0 are not objects to be subjected to the “01” first-step write verify operation, and therefore, they are kept unchanged.

Table 6 shows the relation between data items before and after the “01” second-step write verify operation of the data storage sections DS1, DS2 and DS3 in the algorithm of writing upper page data to the same memory cell M shown in FIG. 13 and the threshold voltage of a corresponding memory cell.

TABLE 6

| | | Threshold voltage Vt of memory cell | |
|---|---|---|---|
| | | Lower than 1.4 V | Not lower than 1.4 V |
| Data DS1/DS2/DS3 | 0/0/1 | 0/0/1 | — |
| before nth “01” | 0/1/1 | 0/1/1 | 1/1/1 |
| second-step | 1/1/1 | 1/1/1 | 1/1/1 |
| write verify | 0/0/0 | 0/0/0 | 0/0/0 |
| | 0/1/0 | 0/1/0 | 0/1/0 |
| | 1/1/0 | 1/1/0 | 1/1/0 |

Data DS1/DS2/DS3 after the nth “01” second-step write verify

As shown in table 6, a value which can be set in the data storage sections DS1, DS2 and DS3 before the nth “01” second-step write verify operation is 0/0/1, 0/1/1, 1/1/1, 0/0/0, 0/1/0 or 1/1/0.

0/0/1 indicates that the threshold voltage of the memory cell does not reach the “01” first-step write verify voltage after the nth write step.

0/1/1 indicates that the threshold voltage of the memory cell has reached the “01” first-step write verify voltage until the nth write step, but the threshold voltage of the memory cell does not reach the “01” second-step write verify voltage until the (n-1)th write step.

1/1/1 indicates that the threshold voltage of the memory cell has reached the “01” second-step write verify voltage until the (n-1)th write step.

The detection result in the “01” second-step write verify operation is not “pass” if the threshold voltage of the memory cell does not reach 1.4V which is the “01” second-step write verify voltage in the nth write step. In this case, data of the data storage section DS1 is kept unchanged.

The detection result in the “01” second-step write verify operation is “pass” if the threshold voltage of the memory cell has reached 1.4V which is the “01” second-step write verify voltage in the nth write step. In this case, data of the data storage section DS1 is changed to “1”. Data of the data storage section DS1 which is “1” is kept unchanged irrespective of the threshold voltage of the memory cell. 0/0/1 is not changed by the “01” second-step write verify operation. Further, 0/0/0, 0/1/0, 1/1/0 are not objects to be subjected to the “01” second-step write verify operation, and therefore, they are kept unchanged.

Table 7 shows the relation between data items before and after the “00” first-step write verify operation of the data storage sections DS1, DS2 and DS3 in the algorithm of writing upper page data to the same memory cell M shown in FIG. 13 and the threshold voltage of a corresponding memory cell.

TABLE 7

| | | Threshold voltage Vt of memory cell | |
|---|---|---|---|
| | | Lower than 2.2 V | Not lower than 2.2 V |
| Data DS1/DS2/DS3 | 0/0/1 | 0/0/1 | — |
| before nth “00” | 0/1/1 | 0/1/1 | — |
| first-step | 1/1/1 | 1/1/1 | — |
| write verify | 0/0/0 | 0/0/0 | 0/1/0 |
| | 0/1/0 | 0/1/0 | 0/1/0 |
| | 1/1/0 | 1/1/0 | 1/1/0 |

Data DS1/DS2/DS3 after the nth “00” first-step write verify

As shown in table 7, a value which can be set in the data storage sections DS1, DS2 and DS3 before the nth “00” first-step write verify operation is 0/0/1, 0/1/1, 1/1/1, 0/0/0, 0/1/0 or 1/1/0.

0/0/0 indicates that the threshold voltage of the memory cell does not reach the “00” first-step write verify voltage until the (n-1)th write step.

0/1/0 indicates that the threshold voltage of the memory cell has reached the “00” first-step write verify voltage until the (n-1)th write step, but does not reach the “00” second-step write verify voltage.

1/1/0 indicates that the threshold voltage of the memory cell has reached the “00” second-step write verify voltage until the (n-1)th write step.

Since there occurs no possibility that the threshold voltage of the memory cell has reached the “00” second-step write verify voltage until the (n-1)th write step, but does not reach the “00” first-step write verify voltage, the state of 1/0/0 is not provided in this example.

The detection result in the “00” first-step write verify operation is not “pass” if the threshold voltage of the memory cell does not reach 2.2V, which is the “00” first-step write verify voltage in the nth write step. In this case, data of the data storage section DS2 is kept unchanged.

Since the detection result in the “00” first-step write verify operation is “pass” if the threshold voltage of the memory cell has reached 2.2V, which is the “00” first-step write verify voltage in the nth write step, data of the data storage section DS2 is changed to “1”. Data of the data storage section DS2 which is “1” is kept unchanged irrespective of the threshold voltage of the memory cell. Further, 0/0/1, 0/1/1, 1/1/1 are not objects to be subjected to the “01” first-step write verify operation and are kept unchanged.

Table 8 shows the relation between data items before and after the “00” second-step write verify operation of the data storage sections DS1, DS2 and DS3 in the write algorithm of upper page data to the same memory cell M shown in FIG. 12 and the threshold voltage of a corresponding memory cell.

TABLE 8

| | | Threshold voltage Vt of memory cell | |
|---|---|---|---|
| | | Lower than 2.4 V | Not lower than 2.4 V |
| Data DS1/DS2/DS3 | 0/0/1 | 0/0/1 | — |
| before nth “00” | 0/1/1 | 0/1/1 | — |
| second-step | 1/1/1 | 1/1/1 | — |
| write verify | 0/0/0 | 0/0/0 | — |
| | 0/1/0 | 0/1/0 | 1/1/0 |
| | 1/1/0 | 1/1/0 | 1/1/0 |

Data DS1/DS2/DS3 after the nth “00” second-step write verify

As shown in table 8, a value which can be set in the data storage sections DS1, DS2 and DS3 before the nth “00” second-step write verify operation is 0/0/1, 0/1/1, 1/1/1, 0/0/0, 0/1/0 or 1/1/0.

0/0/0 indicates that the threshold voltage of the memory cell does not reach the “00” first-step write verify voltage after the nth write step.

0/1/0 indicates that the threshold voltage of the memory cell has reached the “00” first-step write verify voltage until the nth write step, but the threshold voltage of the memory cell does not reach the “00” second-step write verify voltage until the (n-1)th write step.

1/1/0 indicates that the threshold voltage of the memory cell has reached the “00” second-step write verify voltage until the (n-1)th write step.

Since there occurs no possibility that the threshold voltage of the memory cell has reached the “00” second-step write verify voltage until the (n-1)th write step, but the threshold voltage of the memory cell does not reach the “00” first-step write verify voltage until the nth write step, the state of 1/0/0 is not provided in this example.

The detection result in the “00” second-step write verify operation is not “pass” if the threshold voltage of the memory cell does not reach 2.4V which is the “00” second-step write verify voltage in the nth write step. In this case, data of the data storage section DS1 is kept unchanged.

The detection result in the “00” second-step write verify operation is “pass” if the threshold voltage of the memory cell has reached 2.4V which is the “00” second-step write verify voltage in the nth write step. In this case, data of the data storage section DS1 is changed to “1”. Data of the data storage section DS1 which is “1” is kept unchanged irrespective of the threshold voltage of the memory cell. 0/0/0 is not changed by the “00” second-step write verify operation. Further, 0/0/1, 0/1/1, 1/1/1 are not objects to be subjected to the “00” second-step write verify operation, and therefore, they are kept unchanged.

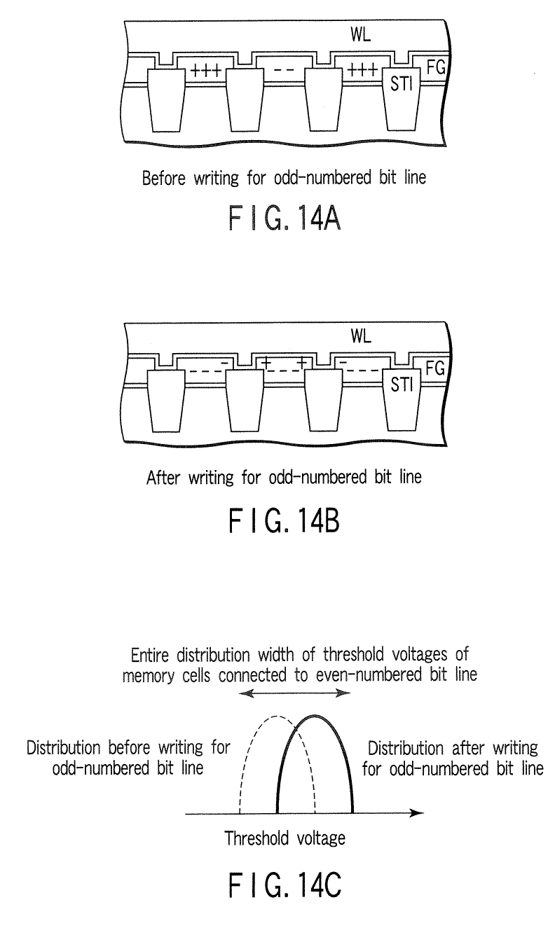

FIGS. 14A to 14C are views and a diagram showing states caused by miniaturization of the processing dimensions of a multi-level flash memory.

FIG. 14A shows a state of charges of the floating gate FG after the write operation is performed for the even-numbered bit line BLe after erasing.

Electrons (−) are charged in the floating gate FG of the memory cell M subjected to the write operation. After this, if the write operation is performed for the odd-numbered bit line BLo, a variation occurs in the state of the floating gate FG of the memory cell M connected to the even-numbered bit line BLe as shown in FIG. 14B. The potential of the even-numbered memory cell M is lowered by the electrostatic capacitive coupling between the adjacent floating gates FG and the threshold voltage is increased as shown in FIG. 14C.

In the above conditions, the technique for narrowing the threshold voltage distribution width becomes extremely important in the future.

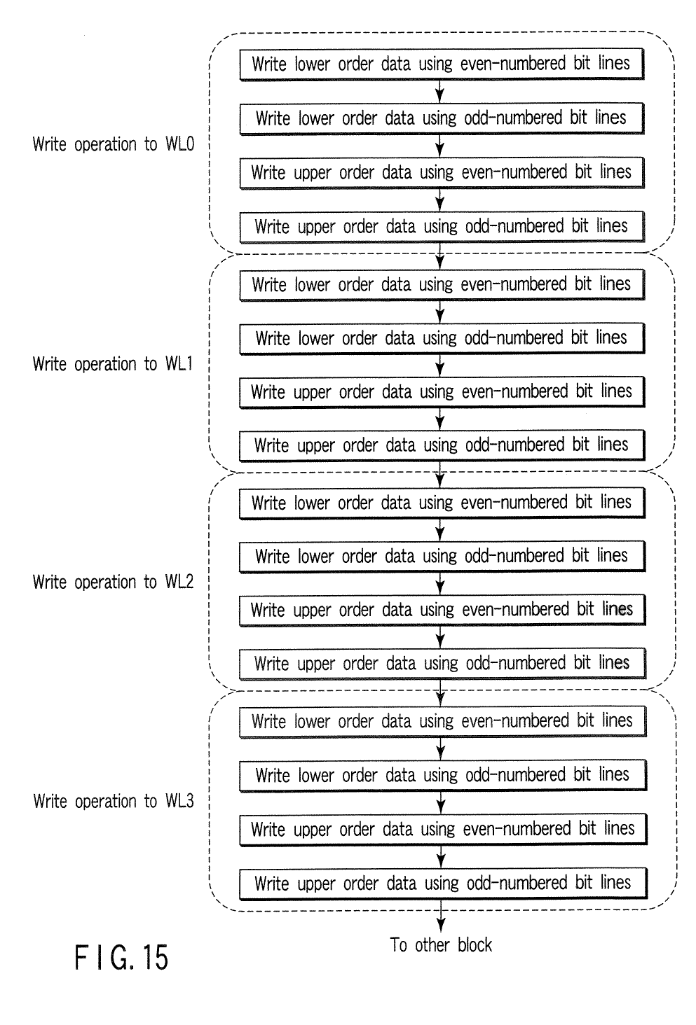

FIG. 15 is a diagram showing a write order in the blocks.

First, a word line WL0 is selected and lower data is written into one page configured by the memory cells M connected to the even-numbered bit lines. Then, lower data is written to one page configured by the memory cells M connected to the odd-numbered bit lines. Thirdly, upper data is written to one page configured by the memory cells M connected to the even-numbered bit lines and, finally, upper data is written to one page configured by the memory cells M connected to the odd-numbered bit lines. After this, the word lines WL1, WL2, WL3 are selected and the write operation is performed in the same manner.

Thus, interference between the adjacent floating gates can be suppressed to minimum. That is, the state of the memory cell M to be subjected to the write operation later is not transited from “11” to “00” even if the state thereof is transited from “11” to “10”, from “11” to “01” or from “10” to “00”. Transition from “11” to “00” causes the threshold voltage of the adjacent memory cell to be most extremely raised.

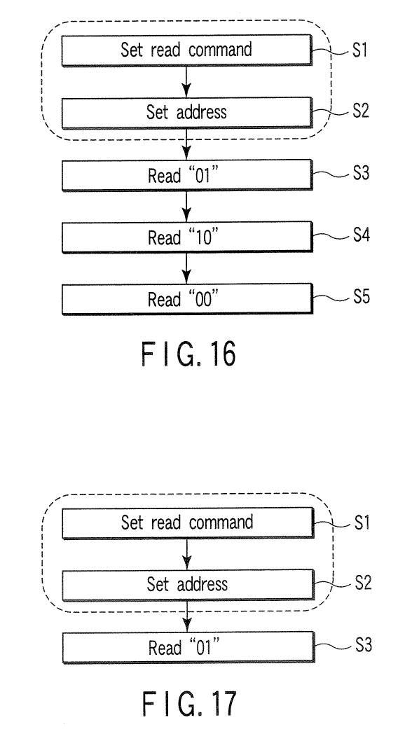

FIG. 16 is a diagram showing a read algorithm of lower page data of the same memory cell M.

First, for example, the command interface 7 receives a read command from the host and sets the read command in the state machine 8 (S1). Next, the command interface 7 receives address data from the host and sets an address to select a read page in the state machine 8 (S2). Thus, the address is set and steps S3 to S5 are automatically started in the internal portion by the state machine 8.

First, the “01” read operation is started (S3). The result of reading is stored in a corresponding data storage section DS3. Next, the “10” read operation is started (S4) and the result of reading is stored in a corresponding data storage section DS2. Finally, the “00” read operation is started (S5) and lower page data is subjected to the logical operation based on data of the data storage sections DS2 and DS3 corresponding to the read result and stored in a corresponding data storage section DS1. The data of the data storage section DS1 is externally output.

FIG. 17 is a diagram showing a read algorithm of upper page data of the same memory cell M.

First, for example, the command interface 7 receives a read command from the host and sets the read command in the state machine 8 (S1). Next, the command interface 7 receives address data from the host and sets an address to select a read page in the state machine 8 (S2). Thus, the address is set and step S3 is automatically started in the internal portion by the state machine 8.

The “01” read operation is started (S3). The read result is upper page data and is stored in a corresponding data storage section DS1. The data of the data storage section DS1 is externally output.

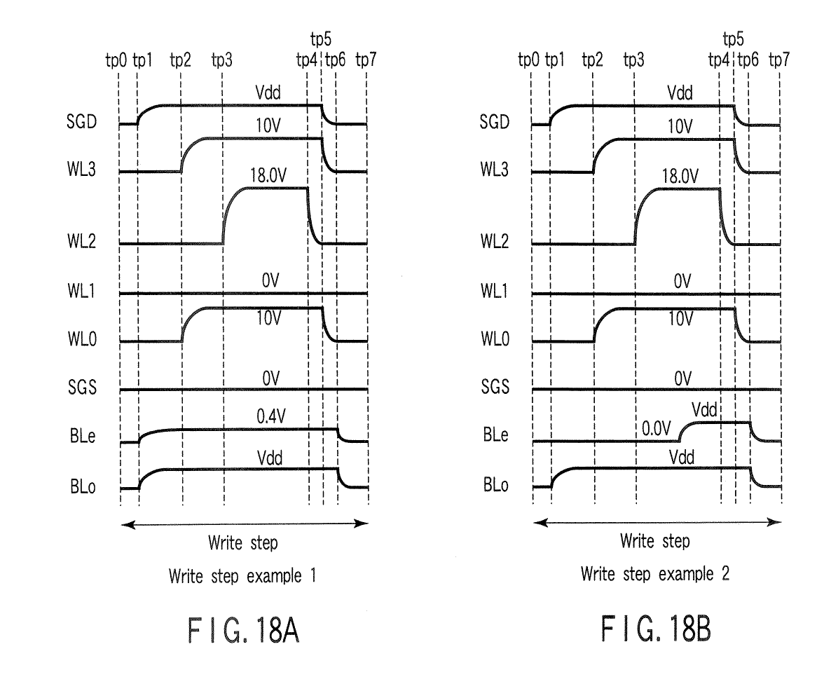

FIG. 18A is an operation waveform diagram showing a write step example 1 shown in FIG. 11. FIG. 18B is an operation waveform diagram showing a write step example 2.

As shown in FIG. 18B, voltage VBL of the bit line BL which is the write control voltage is not set to 0.4V, but is set and kept at 0V for a preset period by applying the write voltage Vpgm to a selected word line WL and is then set at Vdd to inhibit the write operation. As a result, the effective write pulse width is reduced, a rise in the threshold voltage is suppressed and the same effect as that obtained when the voltage VBL of the bit line BL which is the write control voltage is set to 0.4V can be obtained.

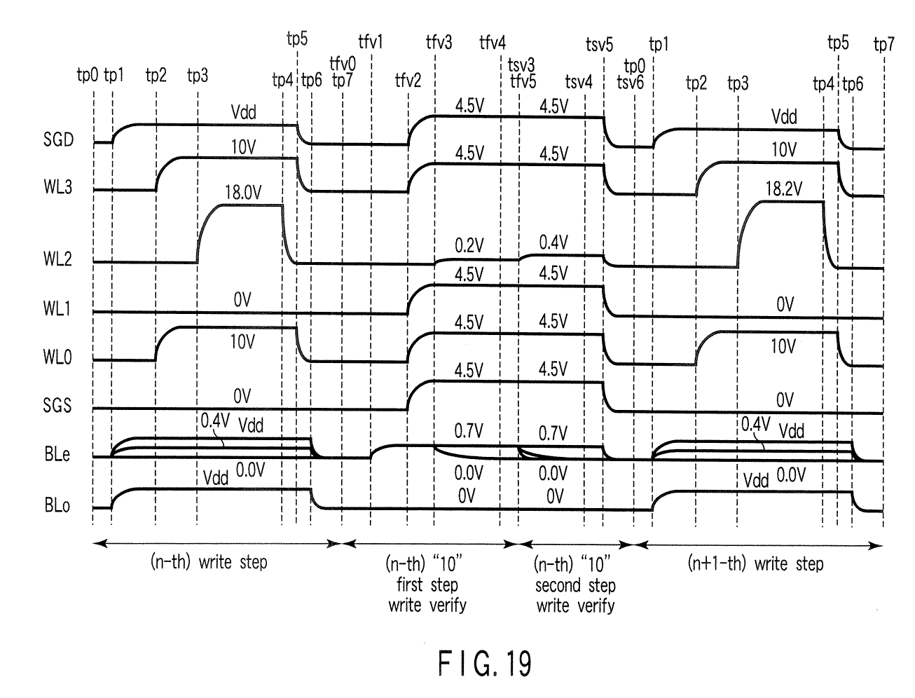

FIG. 19 is an operation waveform diagram showing a modification of the write verify operation shown in FIG. 11.

As shown in FIG. 19, at the time of first-step write verify, first, the bit line BLe is charged to 0.7V. After this, when the potential of the selected word line WL2 reaches the first-step write verify voltage or if the threshold voltage of the memory cell M reaches the first-step write verify voltage, 0.7V is maintained. Further, if the threshold voltage of the memory cell M does not reach the first-step write verify voltage, the voltage is lowered towards 0V. If the voltage of the bit line BLe is detected at the timing tfv4, whether or not the threshold voltage of the memory cell M reaches the first-step write verify voltage can be detected. If the threshold voltage of the memory cell M reaches the write verify voltage, the detection result is “pass”.

After this, the voltage of the selected word line WL2 is switched from the first-step write verify voltage to the second-step write verify voltage at the timing tfv5 or at the same timing tsv3. If the threshold voltage of the memory cell M reaches the second-step write verify voltage, 0.7V is maintained. Further, if the threshold voltage of the memory cell M does not reach the second-step write verify voltage, the voltage is lowered towards 0V. If the voltage of the bit line BLe is detected at the timing tsv4, whether or not the threshold voltage of the memory cell M reaches the second-step write verify voltage can be detected. If the threshold voltage of the memory cell M reaches the write verify voltage, the detection result is “pass”.

Thus, the charging time of the bit line at the time of second-step write verify can be omitted and the write operation can be more rapidly performed. The “01” or “00” first-step or second-step write verify operation can be performed in the same manner simply by changing the write verify voltage.

The semiconductor integrated circuit device according to this example further includes the following configuration.

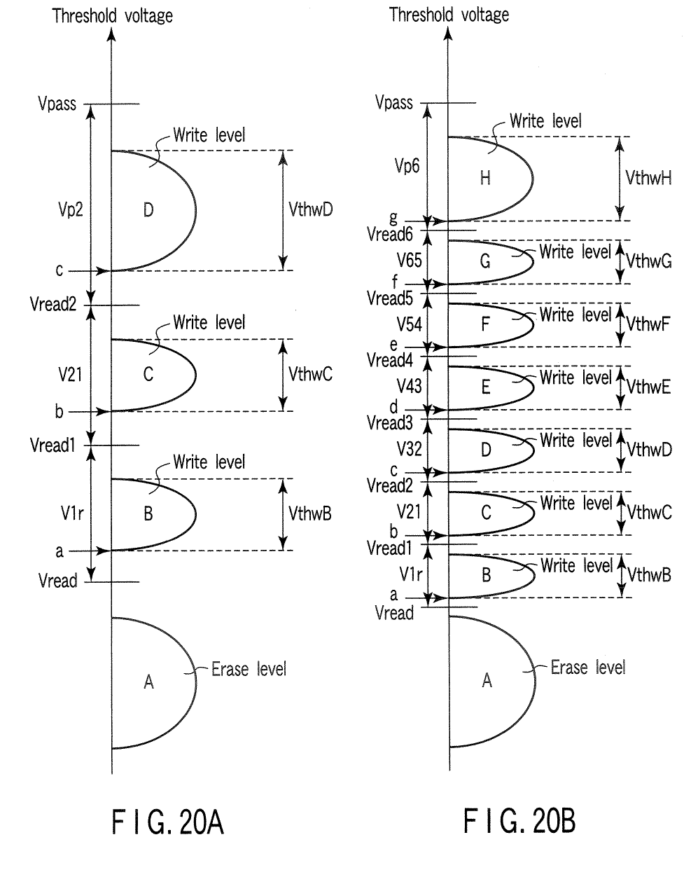

FIGS. 20A and 20B are diagrams showing distribution of the threshold voltages of the NAND flash memory according to the first embodiment of this invention. FIG. 20A shows one example of a case of 4-level storage (2-bit storage) and FIG. 20B shows one example of a case of 8-level storage (3-bit storage). The present embodiment and embodiments which will be described later can be applied to a nonvolatile semiconductor memory which can store data of 3-level or multi-level data which is not limited to 4-level data and 8-level data.

In the case of 4-level storage, as shown in FIG. 20A, threshold voltage distributions A, B, C and D are provided in order from the lowest threshold voltage. In the case of 8-level storage, as shown in FIG. 20B, threshold voltage distributions A, B, C, D, E, F, G and H are provided in order from the lowest threshold voltage. The lowest threshold voltage distribution A is an erase level and set at a negative value, for example. In this example, the other distributions are write levels. The highest write level is the distribution D in the case of 4-level storage and is the distribution H in the case of 8-level storage.

In this example, the threshold voltage distribution width Vthw at the highest write level is larger than the threshold voltage distribution width Vthw at the other write levels. For example, in the example shown in FIG. 20A, the distribution width VthwD of the distribution D is larger than the distribution width VthwC of the distribution C and the distribution width VthwB of the distribution B. Likewise, in the example shown in FIG. 20B, the distribution width VthwH of the distribution H is larger than the distribution width VthwG of the distribution G, . . . , and the distribution width VthwB of the distribution B.

Further, in this example, the potential difference between read voltage Vread used to determine whether the voltage is set at the highest write level or next-highest write level and intermediate voltage Vpass is larger than the potential difference between the other read voltages. For example, in the example shown in FIG. 20A, the potential difference Vp2 between read voltage Vread2 used to determine whether the voltage is set at the write level D or write level C and the intermediate voltage Vpass is larger than the potential difference V21 between the read voltage Vread2 and read voltage Vread1 used to determine whether the voltage is set at the write level C or write level B and the potential difference V1r between the read voltage Vread1 and the read voltage Vread used to determine whether the voltage is set at the write level B or erase level A. Likewise, in the example shown in FIG. 20B, the potential difference Vp6 between read voltage Vread6 used to determine whether the voltage is set at the write level H or write level G and the intermediate voltage Vpass is larger than the potential difference V65 between the read voltage Vread6 and read voltage Vread5 used to determine whether the voltage is set at the write level G or write level F, . . . , and the potential difference V1r between the read voltage Vread1 and the read voltage Vread used to determine whether the voltage is set at the write level B or erase level A.

Thus, an advantage that the distribution width Vthw of the threshold voltages of the highest write level can be easily enlarged can be attained by setting the potential difference between the read voltage Vread used to determine whether the voltage is set at the highest write level or next-highest write level and the intermediate voltage Vpass larger than the potential difference between the other read voltages.

Reference symbols a, b, c, d, e, f, g shown in FIGS. 20A, 20B, indicate verify voltages applied to the word line at the verify read time.

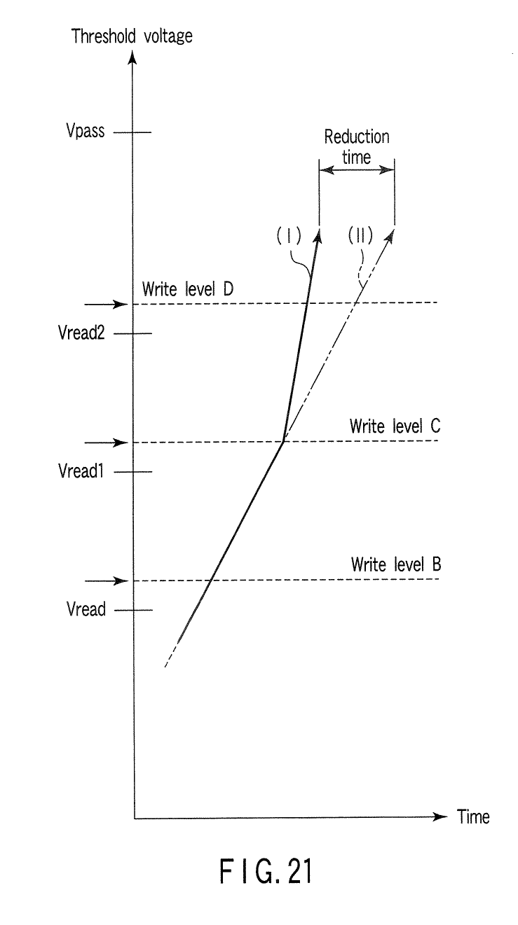

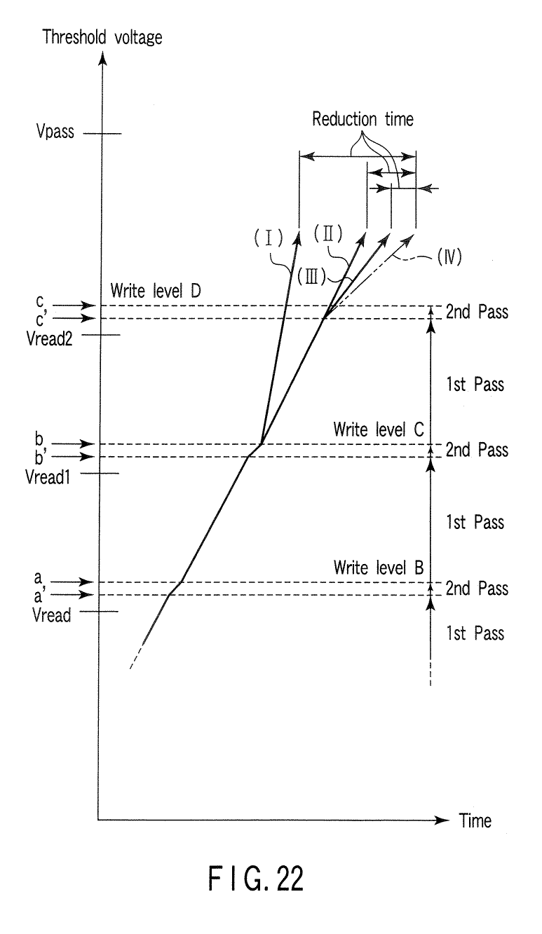

FIGS. 21, 22 show the effects attained in the first embodiment. In FIG. 21, a case wherein the write levels B, C, D are sequentially written is shown as one example. Further, only a case of 4-level storage is shown, but it is needless to say that the same effect can be attained in the case of 8-level storage.

In FIG. 21, the degree of rising of the threshold voltage is schematically shown. That is, the ordinate indicates the level of the threshold voltage and the abscissa indicates time.

The fact that the distribution width VthwD of the write level D is larger than the other distribution widths VthwC, VthwB indicates that the step-up width of the word line voltage at the time of writing of the write level D can be set larger than the step-up width at the time of writing of the write level C, B.

Therefore, as shown by the line (I) in FIG. 21, for example, the degree of rising of the threshold voltage becomes abrupt when it rises from the write level C to the write level D. The line (II) indicates a case wherein the step-up width is kept unchanged, but the degree of rising of the threshold voltage smoothly varies in comparison with the line (I) when it rises from the write level C to the write level D. The difference between the inclinations of the lines (I) and (II) appears in the form of “a reduction in the write time” in an actual device.

FIG. 22 shows a case wherein the pass write method or quick-pass write method is applied to the write method shown in FIG. 21. Reference symbols a′, b′, c′ shown in FIG. 22 indicate the first-step verify voltages at the time of 1^{st} Pass and reference symbols a, b, c indicate the second-step verify voltages at the time of 2^{nd} Pass.

As shown in FIG. 22, when the pass write method or quick-pass write method is applied, the method can be roughly divided into three methods.

1. Like the example shown in FIG. 21, the step-up width is increased at the time of writing of the write level D (refer to the line (I)). The pass write method or quick-pass write method is not used at the time of writing of the write level D.

2. The pass write method or quick-pass write method is not used at the time of writing of the write level D. The point different from the method 1 is that the step-up width at the time of writing of the write level D is the same as the step-up width at the time of 1^{st} Pass. However, even if the first-step verify write voltage C′ is reached, the step-up width is not reduced (refer to the line (II)).

3. The pass write method or quick-pass write method is used at the time of writing of the write level D. However, the step-up width at the time of 2^{nd} Pass in the case of writing of the write level D is set larger than the step-up width at the time of 2^{nd} Pass in the case of writing of the write level C, B (refer to the line (III)).

In each of the above cases, the write time can be reduced in comparison with a case (refer to the line (IV)) wherein the same pass write method or quick-pass write method as that at the time of writing of the write level C, B is used at the time of writing of the write level D.

The write method which realizes the first embodiment is not limited to the methods shown in FIGS. 21, 22. For example, the methods 1 to 3 shown in FIG. 22 may be combined and it is additionally noted that a method other than the methods 1 to 3 is provided.

As described above, according to the first embodiment, the write operation speed can be enhanced by setting both of the large distribution width and small distribution width in the distribution width of the threshold voltages of the write level.

For example, in order to change the step-up width, data written may be referred to. Data written is held in a page buffer, for example. Therefore, the step-up width may be changed when data of the page buffer is referred to and it is detected that data in which the step-up width is to be changed is provided.

Further, when data of the page buffer is referred to, write data of the page buffer is referred to and the step-up width may be changed by use of a simultaneous detection circuit.

Further, when data of the page buffer is referred to, write data of the page buffer is output via the I/O line and the thus output write data may be referred to.

### Second Embodiment

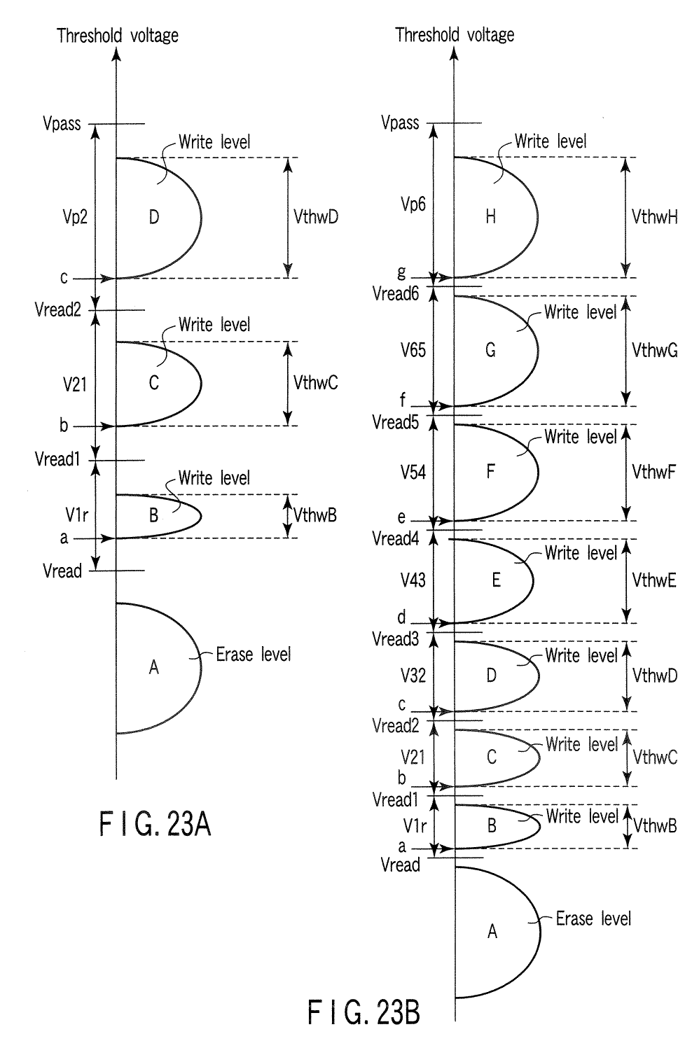

In the first embodiment, one write threshold voltage distribution width is changed from the other write threshold voltage distribution width. However, the distribution width to be changed is not limited to one. All of the two or more write threshold voltage distribution widths may be changed. One example is shown in FIGS. 23A and 23B. FIG. 23A shows one example of a case of 4-level storage (2-bit storage) and FIG. 23B one example of a case of 8-level storage (3-bit storage).

In this example, the threshold voltage distribution widths Vthw of two or more write levels are set different from one another. Particularly, in this example, the distribution width Vthw is made larger as the write level is set higher.

In the example shown in FIG. 23A, the relation between the distribution widths VthwB to VthwD is set as follows.
VthwB<VthwC<VthwD

Likewise, in the example shown in FIG. 23B, the relation between the distribution widths VthwB to VthwH is set as follows.
VthwB<VthwC< . . . <VthwG<VthwH

Further, in this example, the potential difference between the read voltages is set larger as the write level is set higher.

In the example shown in FIG. 23A, the relation between the potential differences V1r to Vp2 is set as follows.
V1r<V21<Vp2

Likewise, in the example shown in FIG. 23B, the relation between the potential differences V1r to Vp6 is set as follows.
V1r<V21<V32< . . . <V54<V65<Vp6

Thus, it is possible to attain an advantage that the distribution width Vthw can be easily made larger as the write level is set higher by setting the potential difference between the read voltages larger as the write level is set higher.

Like the first embodiment, in the second embodiment, the write operation speed can be enhanced by setting both of the large distribution width and small distribution width in the distribution widths of the threshold voltages of write levels.

Next, modifications of the second embodiment are explained.

(First Modification)

Like the first embodiment, the first modification is to maintain the distribution widths of the threshold voltages of write levels other than the highest write level while the potential differences between the read voltages are set to different values.

The threshold voltage of a nonvolatile semiconductor memory cell is changed by forcibly injecting electrons into the floating gate. The nonvolatile semiconductor memory cell is also one of the physical structures. Since it is the physical structure, it has a physically stable state. Further, forcibly injecting electrons into the floating gate shifts the state from the physically stable state to an unstable state. The physical structure set in the unstable state tends to return to the stable state. By taking this phenomenon into consideration, the present modification is to set the potential difference between the read voltages smaller in a state closer to the stable state and set the potential difference between the read voltages larger in a state farther apart from the stable state.

One of the stable states is 0V from the viewpoint of the potential. In the present modification, the potential difference between the read voltages is made smaller as the write level is set closer to 0V and the potential difference between the read voltages is made larger as the write level is set farther apart from 0V.

If the data holding time becomes longer, the degree of lowering of the voltage toward 0V becomes higher as the write level is set farther apart from 0V. In the present modification, the potential difference between the read voltages is made larger as the write level is set farther apart from 0V.

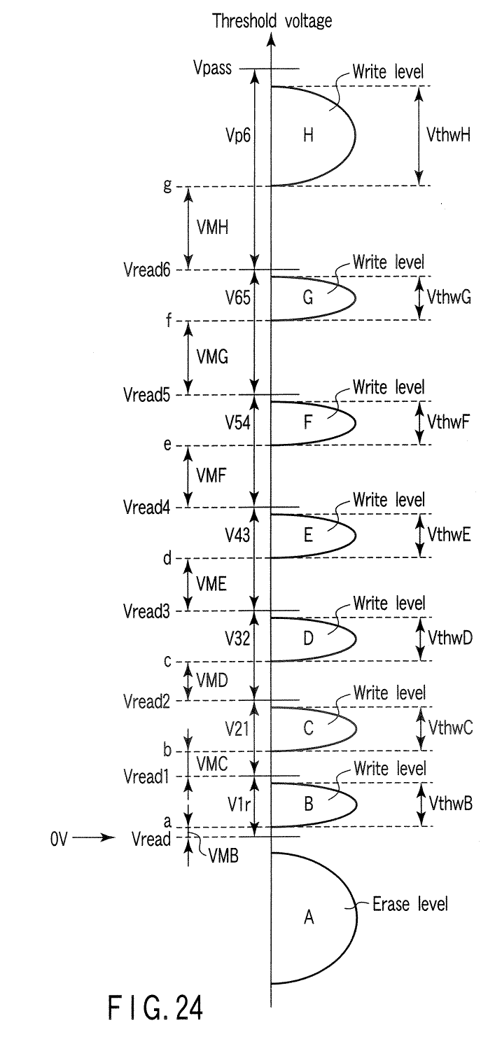

Further, in the present modification, the difference between the read voltage and the lowest threshold voltage or a so-called margin VM is made larger as the write level is set farther apart from 0V. One example is shown in FIG. 24. Specifically, the relation between the margins VMB to VMH is expressed as follows.
VMB<VMC<VMD<VME<VMF<VMG<VMH

By setting the write threshold voltage distribution as shown in FIG. 24, it becomes possible to suppress that the write level is lowered and becomes lower than the read voltage even when the data holding time becomes long. Therefore, an advantage that the data holding characteristic is enhanced can be attained.

In the present modification, the distribution width of the threshold voltages of the highest write level is set so as to enlarge the threshold voltage distribution widths of the other write levels. However, as explained in the second embodiment, it is possible to change the threshold voltage distribution widths of two or more write levels. Also, in this case, in order to attain the advantage that the data holding characteristic is enhanced, the margin may be set larger as the write level is set farther apart from 0v.

(Second Modification)

A second modification is different from the first modification in that stable portions are specified based not on the viewpoint of the potential but on the viewpoint of the physical property of semiconductor.

As the portion in which the characteristic of the nonvolatile semiconductor memory is stabilized, a portion corresponding to so-called neutral threshold voltage Vth* is provided. The neutral threshold voltage is threshold voltage obtained by, for example, applying ultraviolet rays to the nonvolatile semiconductor memory cell and then extracting electrons from the floating gate. The threshold voltage of the nonvolatile semiconductor memory cell tends to be converged to the neutral threshold voltage if it is left as it is for a long period of time.

The nonvolatile semiconductor memory is generally incorporated into an electronic equipment system. When it is incorporated into the system, the power supply voltage is applied thereto even if it is not accessed. That is, electrical stress is applied to the nonvolatile semiconductor memory. In this case, it is permissible to consider that a portion in which the characteristic is stabilized is 0V.

However, recently, the nonvolatile semiconductor memories are used in storage media of smart cards (IC cards) or memory cards. The smart card or memory card is not inserted into an electronic equipment and is left as it is for a long period of time in many cases. For example, the fact that the smart card or memory card is not inserted into the electronic equipment indicates that it is left as it is for a long period while electrical stress is not applied to the nonvolatile semiconductor memory. In this case, it is permissible to consider that a portion in which the characteristic is stabilized is the neutral threshold voltage Vth*.

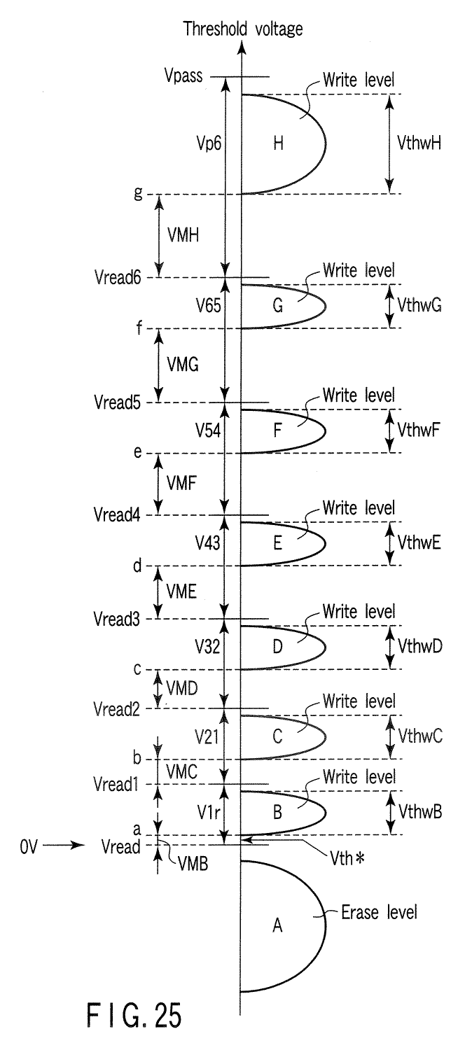

Therefore, in the present modification, the potential difference between the read voltages is made smaller as the write level is set closer to the neutral threshold voltage Vth* and the potential difference between the read voltages is made larger as the write level is set farther apart from the neutral threshold voltage Vth*. Further, in the present modification, as the write level is set farther apart from the neutral threshold voltage Vth*, the potential difference between the read voltages is made larger and a difference between the read voltage and the lowest threshold voltage or a so-called margin is made larger. One example is shown in FIG. 25.

By setting the write threshold voltage distribution as shown in FIG. 25, the same advantage as that in the first modification can be attained.

In the present modification, the neutral threshold voltage Vth* is set between 0V and verify voltage Va and the neutral threshold voltage Vth* may be set to a different voltage. For example, it may be set between the read voltage Vread2 and verify voltage c. In this case, as the write level is set farther apart from the neutral threshold voltage Vth*, the potential difference between the read voltages may be made larger and a difference between the read voltage and the lowest threshold voltage or a so-called margin may be made larger.

In the present modification, as explained in the second embodiment, the threshold voltage distribution widths of two or more levels may be changed. Also, in this case, in order to attain the advantage that the data holding characteristic is enhanced, the margin may be set larger as the write level is set farther apart from the neutral threshold voltage Vth*.

### Third Embodiment

The present embodiment relates to one example of the step-up width of write voltage applied to the word line.

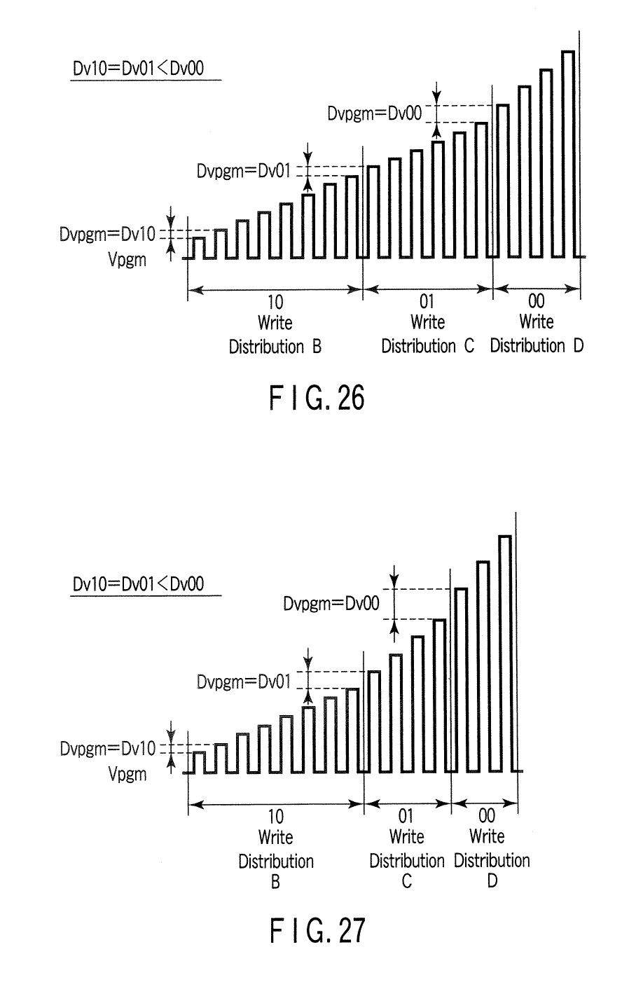

FIG. 26 is a diagram showing distribution of the threshold voltages of a NAND flash memory according to a first example of a third embodiment of this invention. For example, the first example is an example of changing the step-up width to attain the threshold voltage distribution of the NAND flash memory according to the first embodiment.

FIG. 26 shows an example of 4-level storage. In this case, the step-up width Dvpgm (=Dv10) at the “10” write (distribution B) time is set to the same as the step-up width Dvpgm (=Dv01) at the “01” write (distribution C) time. Further, the step-up width Dvpgm (=Dv00) at the “00” write (distribution D) time may be set larger than the step-up widths Dv10 and Dv01.

That is, the relation of Dv10=Dv01<Dv00 is set. This applies to a case other than the 4-level storage.

FIG. 27 is a diagram showing distribution of the threshold voltages of a NAND flash memory according to a second example of the third embodiment of this invention. For example, the second example is an example of changing the step-up width to attain the threshold voltage distribution of the NAND flash memory according to the second embodiment.

FIG. 26 shows an example of 4-level storage. In this case, the step-up width Dvpgm (=Dv01) at the “01” write (distribution C) time is set larger than the step-up width Dvpgm (=Dv10) at the “10” write (distribution B) time. Further, the step-up width Dvpgm (=Dv00) at the “00” write (distribution D) time may be set larger than the step-up width Dv01.

That is, the relation of Dv10<Dv01<Dv00 is set. This applies to a case other than the 4-level storage.

### Fourth Embodiment

The present embodiment relates to one example of a method of attaining narrow threshold voltage distribution.

The storage capacity of a data rewritable nonvolatile semiconductor memory, for example, a NAND flash memory tends to increase more and more.

When memory cells are more miniaturized as the storage capacity increases more and more, for example, a phenomenon which is difficult to appear so far, for example, a variation in the threshold voltage caused by the potential of the floating gate of an adjacent cell comes to appear. The variation in the threshold voltage is called a proximity effect. The proximity effect causes the threshold voltage of the memory cell to which data has been written to vary. This may cause an erroneous data writing operation.

A write method called as an LM write method is provided as a method of suppressing a variation in the threshold voltage of the memory cell to which data has been written and setting the narrow threshold voltage distribution. The present embodiment is attained by applying the first embodiment to the LM write method.

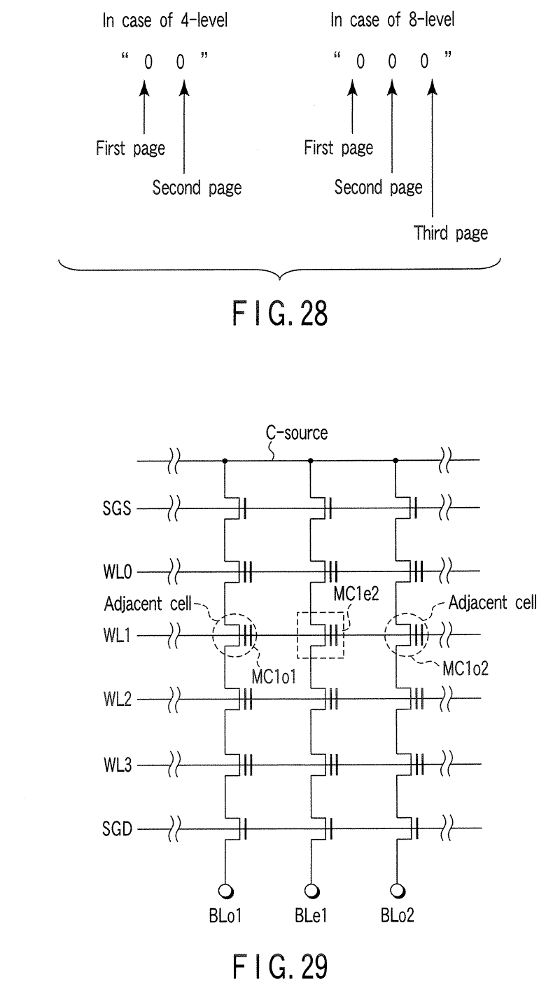

First, the definition of a page in the LM write method is explained. The definition of the page is shown in FIG. 28. In the LM write method of this example, the pages are so defined that the highest bit is set as the first page, and pages towards the lowest bit are sequentially set as second page, third page, In FIG. 28, cases of four values and eight values are shown, but the same applies to a case other than the cases of four values and eight values, for example. FIG. 29 shows a cell to which data is written and cells lying around the above cell.

It is assumed that the proximity effect is caused in data written to a memory cell connected to an even-numbered bit line BLe (BLe2) shown in FIG. 29 by data written into memory cells connected to odd-numbered bit lines BLo (BLo1, BLo2). For example, the proximity effect occurs in data written to the cell MC1e2 due to data written to cells MC1o1, MC1oadjacent to the cell MC1e2.

(In Case of 4-Level Storage)

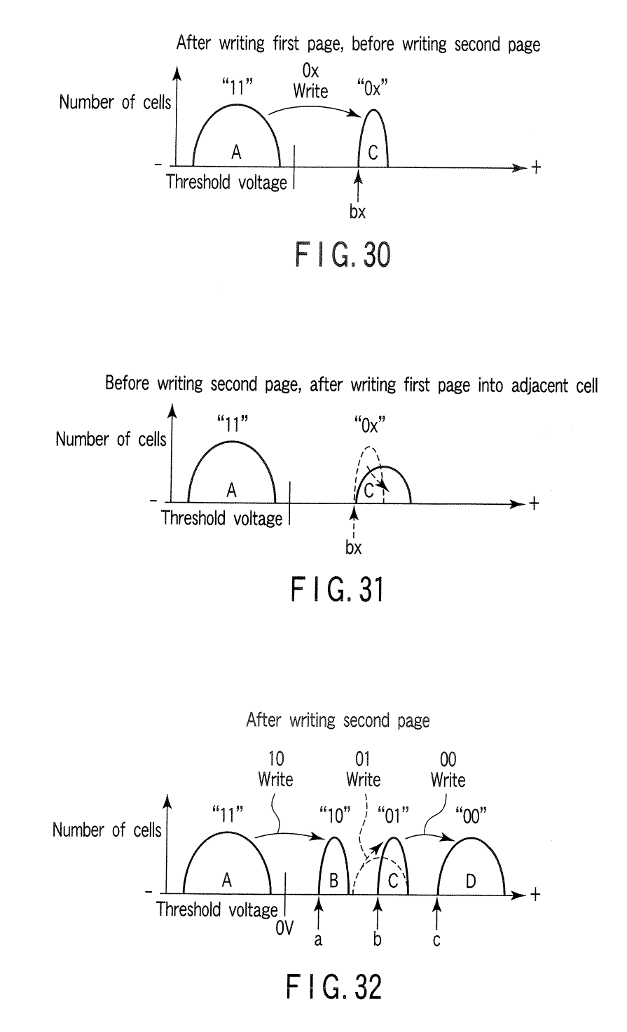

FIGS. 30 to 32 are diagrams showing threshold voltage distributions of the memory cells connected to the even-numbered bit line BLe for respective main write stages.

First, data of a first page is written to a memory cell connected to the even-numbered bit line BLe. As shown in FIG. 30, if the first page data is “1”, the threshold voltage maintains the erase level “11 (distribution A)”. If it is “0”, the “0x” writing operation is performed to shift the threshold voltage from the erase level “11” to the write level “0x (distribution C)”. The reference symbol “bx” indicates “0x” level verify voltage.

After this, the first page data is written to a memory cell connected to the odd-numbered bit line BLo. The threshold voltage distribution of the memory cell connected to the even-numbered bit line BLe after the first page data is written to the memory cell connected to the odd-numbered bit line BLo is shown in FIG. 31.

As shown in FIG. 31, the threshold voltage distribution of the write level “0x” is influenced by the first page data written to the adjacent cell and is widened.

Next, data of a second page is written to the memory cell connected to the even-numbered bit line BLe.

As shown in FIG. 32, if the first page data is “1” and the second page data is “1”, the threshold voltage maintains the erase level “11”.

Further, if the first page data is “1” and the second page data is “0”, the “10” write operation is performed to shift the threshold voltage from the erase level “11” to the write level “10 (distribution B)”. The reference symbol “a” indicates “10” level verify voltage.

If the first page data is “0” and the second page data is “1”, the “01” write operation is performed to shift the threshold voltage from the write level “0x” to the write level “01”. The reference symbol “b” indicates “01” level verify voltage. By the “01” write operation, the threshold voltage distribution which is widened with the write level “0x” shown in FIG. 31 is narrowed.

Further, if the first page data is “0” and the second page data is “0”, the “00” write operation is performed to shift the threshold voltage from the write level “0x” to the write level “00 (distribution D)”. The reference symbol “c” indicates “00” level verify voltage.

In this example, the step-up width of the word line voltage at the “00” write time is set larger than the step-up width at the “10” write time or “01” write time. Thus, as shown in FIG. 32, the same threshold voltage distribution as that of the first embodiment can be attained. Then, by setting the step-up width of the word line voltage in the “00” write operation larger than the step-up width in the other write operation, the write operation speed can be enhanced like the first embodiment.

(In Case of 8-Level Storage)

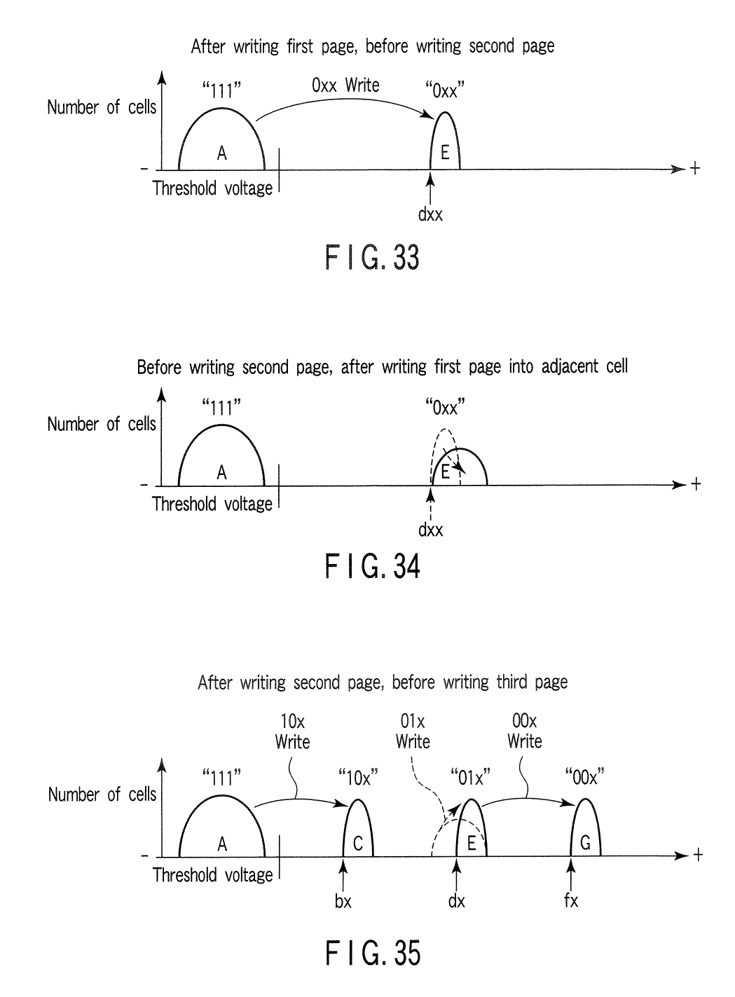

FIGS. 33 to 37 are diagrams showing threshold voltage distributions of the memory cells connected to the even-numbered bit line BLe for respective main write stages.

First, data of a first page is written to a memory cell connected to the even-numbered bit line BLe. As shown in FIG. 33, if the first page data is “1”, the threshold voltage maintains the erase level “111 (distribution A)”. If it is “0”, the “xx” write operation is performed to shift the threshold voltage from the erase level “111” to the write level “0xx (distribution E)”. The reference symbols “dxx” indicates “0xx” level verify voltage.

After this, the first page data is written to the memory cell connected to the odd-numbered bit line BLo. The distribution of the threshold voltage of the memory cell connected to the even-numbered bit line BLe after the first page data is written to the memory cell connected to the odd-numbered bit line BLo is shown in FIG. 34.

As shown in FIG. 34, the threshold voltage distribution of the write level “0xx” is influenced by the first page data written to the adjacent cell and is widened.

Next, data of a second page is written to the memory cell connected to the even-numbered bit line BLe.

As shown in FIG. 35, if the first page data is “1” and the second page data is “1”, the threshold voltage maintains the erase level “111”.

Further, if the first page data is “1” and the second page data is “0”, the “10x” write operation is performed to shift the threshold voltage from the erase level “111” to the write level “10x (distribution C)”. The reference symbol “bx” indicates “10x” level verify voltage.

If the first page data is “0” and the second page data is “1”, the “01x” write operation is performed to shift the threshold voltage from the write level “0xx” to the write level “01x (distribution E)”. The reference symbol “dx” indicates “01x” level verify voltage. By the “01x” write operation, the threshold voltage distribution which is widened with the write level “0xx” shown in FIG. 34 is narrowed.

Further, if the first page data is “0” and the second page data is “0”, the “00x” write operation is performed to shift the threshold voltage from the write level “0xx” to the write level “00x (distribution G)”. The reference symbol “fx” indicates “00x” level verify voltage.

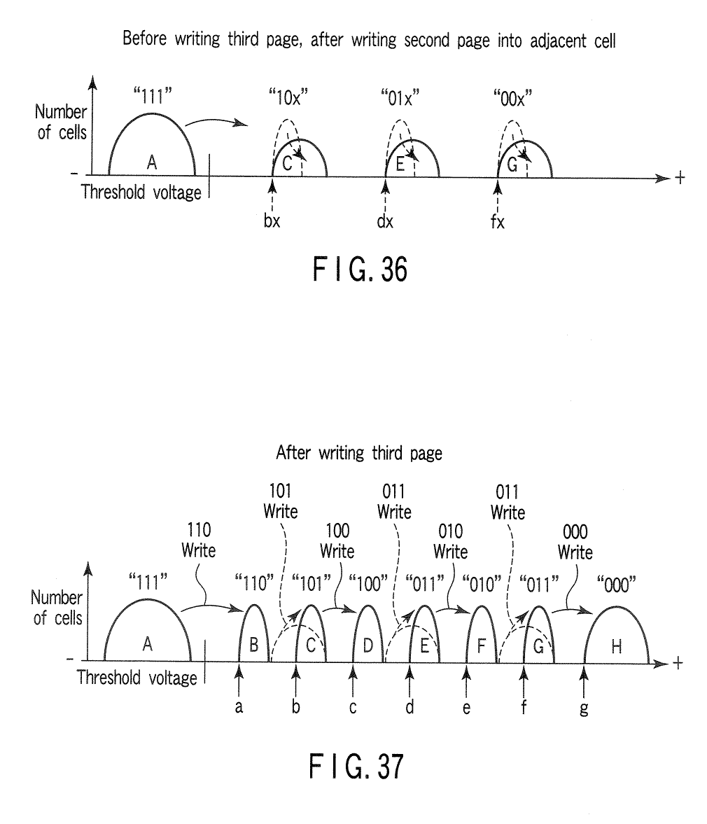

After this, the second page data is written to the memory cell connected to the odd-numbered bit line BLo. The threshold voltage distribution of the memory cell connected to the even-numbered bit line BLe after the second page data is written to the memory cell connected to the odd-numbered bit line BLo is shown in FIG. 36.

As shown in FIG. 36, the threshold voltage distributions of the write levels “10x”, “01x”, “00x” are influenced by the second page data written to the adjacent cell and are widened.

Next, data of a third page is written to the memory cell connected to the even-numbered bit line BLe.

As shown in FIG. 37, if the first page data is “1”, the second page data is “1” and the third page data is “1”, the threshold voltage maintains the erase level “111”.

Further, if the first page data is “1”, the second page data is “1” and the third page data is “0”, the “110” write operation is performed to shift the threshold voltage from the erase level “111” to the write level “110 (distribution B)”. The reference symbol “a” indicates “110” level verify voltage.

If the first page data is “1”, the second page data is “0” and the third page data is “1”, the “101” write operation is performed to shift the threshold voltage from the write level “10x” to the write level “101 (distribution C)”. The reference symbol “b” indicates “101” level verify voltage. By the “101” write operation, the threshold voltage distribution which is widened with the write level “10x” shown in FIG. 36 is narrowed.

Further, if the first page data is “1”, the second page data is “0” and the third page data is “0”, the “100” write operation is performed to shift the threshold voltage from the write level “10x” to the write level “100 (distribution D)”. The reference symbol “c” indicates “100” level verify voltage.

If the first page data is “0”, the second page data is “1” and the third page data is “1”, the “011” write operation is performed to shift the threshold voltage from the write level “01x” to the write level “011 (distribution E)”. The reference symbol “d” indicates “011” level verify voltage. By the “011” write operation, the threshold voltage distribution which is widened with the write level “01x” shown in FIG. 36 is narrowed.

If the first page data is “0”, the second page data is “1” and the third page data is “0”, the “010” write operation is performed to shift the threshold voltage from the write level “01x” to the write level “010 (distribution F)”. The reference symbol “e” indicates “010” level verify voltage.

Further, if the first page data is “0”, the second page data is “0” and the third page data is “1”, the “001” write operation is performed to shift the threshold voltage from the write level “00x” to the write level “001 (distribution G)”. The reference symbol “f” indicates “001” level verify voltage. By the “001” write operation, the threshold voltage distribution which is widened with the write level “00x” shown in FIG. 36 is narrowed.

If the first page data is “0”, the second page data is “0” and the third page data is “0”, the “000” write operation is performed to shift the threshold voltage from the write level “00x” to the write level “000 (distribution H)”. The reference symbol “g” indicates “000” level verify voltage.

In this example, the step-up width of the word line voltage in the “000” write operation is set larger than the step-up width in the other write operation. Thus, as shown in FIG. 37, the same threshold voltage distribution as that of the first embodiment can be attained. Like the first embodiment, the write operation speed can be enhanced by setting the step-up width of the word line voltage in the “000” write operation larger than the step-up width in the other write operation.

Thus, the first embodiment can be applied to the LM write method.

Not only the first embodiment but also the second embodiment can be applied to the LM write method although not shown in the drawing.

Further, the above embodiments contain the following items.

(1) A semiconductor integrated circuit device includes a semiconductor chip, and data rewritable nonvolatile memory cells which are formed on the chip and in which it is permissible to store data of not less than three values, wherein at least two write threshold voltage distribution widths are changed according to at least two write levels.

(2) In the device described in item (1), the threshold voltage distribution width of the highest write level among the at least two threshold voltage distribution widths is the largest.

(3) In the device described in item (1), the step-up width of the write voltage applied to the word line is changed according to the at least two write levels when data is written to the nonvolatile memory cell.

(4) In the device described in item (3), the step-up width at the write time of the highest write level among the step-up widths of the write voltage applied to the word line is the largest.

(5) In the device described in one of items (1) to (4), the nonvolatile memory cell is a NAND memory cell, intermediate voltage and read voltages of at least two steps are applied to the word line when data is read from the NAND nonvolatile memory cell, and the potential difference between the intermediate voltage and first read voltage which determines whether the voltage is set at the highest write level or next-highest write level among the read voltages of at least two steps is larger than the potential difference between other read voltages.

(6) In the device described in one of items (3) and (4), the step-up width is changed with reference to data of the page buffer.

(7) In the device described in any one of items (3), (4) and (6), data of the page buffer is referred to by use of a simultaneous detection circuit.

(8) In the device described in any one of items (3), (4) and (6), data of the page buffer is referred to based on data output via the I/O line.

(9) In the device described in any one of items (1) to (8), the write method is one of the pass write method and quick-pass write method.

(10) In the device described in any one of items (1) to (8), the write method is the LM write method.

According to the semiconductor integrated circuit device according to the embodiments of this invention, a semiconductor integrated circuit device having an electrically rewritable nonvolatile semiconductor memory device in which the write operation speed can be increased can be provided.

This invention has been explained by use of several embodiments, but this invention is not limited to the above embodiments and can be variously modified without departing from the technical scope of this invention at the time of embodying the same.

Further, the above embodiments can be performed independently, and can be also adequately combined and performed.

The above embodiments contain inventions of various stages and the inventions of various stages can be extracted by adequately combining a plurality of constituents disclosed in the embodiments.

In addition, the embodiments are explained based on the example in which this invention is applied to a NAND flash memory. However, this invention is not limited to a NAND flash memory and can also be applied to an AND or NOR flash memory other than a NAND flash memory. Further, a semiconductor integrated circuit device containing the above flash memory, for example, a processor, system LSI or the like is contained in the scope of this invention.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor integrated circuit device comprising:
a semiconductor chip, and
data rewritable nonvolatile memory cells which are formed on the chip and in which it is permissible to store data of not less than three values,
wherein at least two write threshold voltage distribution widths are changed according to at least two write levels.

2. The device according to claim 1, wherein the threshold voltage distribution width of the highest write voltage is the largest among the at least two write threshold voltage distribution widths.

3. The device according to claim 1, wherein step-up widths of write voltages applied to a word line are changed according to the at least two write levels when data is written into the nonvolatile memory cell.

4. The device according to claim 1, wherein step-up width at the time of writing of the highest write level is the largest among the step-up widths of write voltages applied to the word line.

5. The device according to claim 1, wherein the nonvolatile memory cell is of a NAND type, intermediate voltage and read voltages of at least two steps are applied to a word line when data is read from the NAND nonvolatile memory cell, and a potential difference between the intermediate voltage and first read voltage which is used to determine whether the voltage is set at the highest write level or next-highest write level among the read voltages of at least two steps is larger than a potential difference between the other read voltages.

6. The device according to claim 2, wherein the nonvolatile memory cell is of a NAND type, intermediate voltage and read voltages of at least two steps are applied to a word line when data is read from the NAND nonvolatile memory cell, and a potential difference between the intermediate voltage and first read voltage which is used to determine whether the voltage is set at the highest write level or next-highest write level among the read voltages of at least two steps is larger than a potential difference between the other read voltages.

7. The device according to claim 3, wherein the nonvolatile memory cell is of a NAND type, intermediate voltage and read voltages of at least two steps are applied to a word line when data is read from the NAND nonvolatile memory cell, and a potential difference between the intermediate voltage and first read voltage which is used to determine whether the voltage is set at the highest write level or next-highest write level among the read voltages of at least two steps is larger than a potential difference between the other read voltages.

8. The device according to claim 4, wherein the nonvolatile memory cell is of a NAND type, intermediate voltage and read voltages of at least two steps are applied to a word line when data is read from the NAND nonvolatile memory cell, and a potential difference between the intermediate voltage and first read voltage which is used to determine whether the voltage is set at the highest write level or next-highest write level among the read voltages of at least two steps is larger than a potential difference between the other read voltages.

9. The device according to claim 5, wherein a method of writing data to the NAND nonvolatile memory cell is one of a pass write method and quick-pass write method.

10. The device according to claim 6, wherein a method of writing data to the NAND nonvolatile memory cell is one of a pass write method and quick-pass write method.

11. The device according to claim 7, wherein a method of writing data to the NAND nonvolatile memory cell is one of a pass write method and quick-pass write method.

12. The device according to claim 8, wherein a method of writing data to the NAND nonvolatile memory cell is one of a pass write method and quick-pass write method.

13. The device according to claim 5, wherein a method of writing data to the NAND nonvolatile memory cell is an LM write method.

14. The device according to claim 6, wherein a method of writing data to the NAND nonvolatile memory cell is an LM write method.

15. The device according to claim 7, wherein a method of writing data to the NAND nonvolatile memory cell is an LM write method.

16. The device according to claim 8, wherein a method of writing data to the NAND nonvolatile memory cell is an LM write method.

17. The device according to claim 3, wherein the step-up width is changed with reference to data of a page buffer.

18. The device according to claim 4, wherein the step-up width is changed with reference to data of a page buffer.
